(19) United States
(12) Patent Application Publication
(10) Pub. No.: US 2026/0278196 A1
(43) Pub. Date: Sep. 17, 2026

(54) SYSTEMS AND METHODS FOR DIGITALLY LOGGING STRUCTURAL DATA OF ROCK SPECIMENS

(71) Applicant: Vektore Exploration Consulting Corporation, Etobicoke (CA)

(72) Inventors: Rogerio MONTEIRO, Etobicoke (CA); Rodrigo FIGUEIREDO, Etobicoke (CA); Sahadia KOOP, Etobicoke (CA); Tiago SOUZA SERIO DOS SANTOS, Etobicoke (CA)

(73) Assignee: Vektore Exploration Consulting Corporation, Etobicoke, ON (CA)

(21) Appl. No.: 19/162,388

(22) PCT Filed: Mar. 4, 2024
(86) PCT No.: PCT/CA2025/050265

§ 371 Date: Sep. 4, 2025

Related U.S. Application Data
(60) Provisional application No. 63/449,988, filed on Mar. 4, 2023.

(51) Int. Cl. G06F 30/17; G06T 7/73; G06T 15/00; G06T 19/00

(52) U.S. Cl. CPC G06F 30/17; G06T 7/73; G06T 15/00; G06T 19/00; G06T 2200/24; G06T 2207/10016; G06T 2207/30181; G06T 2210/21; G06T 2219/004

(57) ABSTRACT

A structural data logging system includes a digital video camera; a display device; at least one user input device; and at least one processor. The at least one processor is configured to: receive video frames and, during receipt of the video frames: display the video frames; process the video frames to detect at least one predetermined machine-readable code; and, if the at least one predetermined machine-readable code is detected: determine a pose of the at least one machine-readable code; receive one or more user selections corresponding to a respective pixel on the display device; based at least on the pose of the at least one machine-readable code at the time each of the one or more user selection is received, calculate a respective 3D coordinate of a corresponding point within a digital 3D model of an object; and augment the digital 3D model with a respective feature at the coordinate.

### CROSS-REFERENCE TO RELATED APPLICATION

This application claims priority to U.S. Provisional Patent Application Ser. No. 63/449,988 filed on Mar. 4, 2023 entitled SYSTEMS AND METHODS FOR DIGITALLY LOGGING STRUCTURAL DATA OF ROCK SPECIMENS, the contents of which are incorporated by reference herein.

### BACKGROUND OF THE DISCLOSURE

In mineral exploration, drilling is the critical and expensive operation of obtaining rock specimens such as core samples from a geological body. Once obtained, the rock specimens are studied in numerous ways for indications that there may be valuable, retrievable mineral deposits in the geological body.

A large number of core samples are typically extracted from a particular geological body in order to provide useful indications of the mineral contents contained within the body. Typically, a given core sample extracted from a geological body is initially an elongate, generally-cylindrical rock specimen of a few centimeters in diameter and several centimeters long. Upon extraction, the core sample is uniquely identified and very often further “sampled” by splitting the generally-cylindrical core sample into, for example, a number of half- and/or quarter- and/or three-quarter cylinders. The individual samples of an initial core sample are then distributed to one or more laboratories for geochemical and/or geometallurgical analysis, as well as to one or more geologists for geological and/or geophysical study and analysis. For example, structurally relevant core samples and pieces thereof form the foundation of Structural Vectoring®—a process of understanding a mineral body using structural geological analysis. This is described, for example, at the website: https://vektore.com/structural-vectoring-in-mineral-exploration (Monteiro).

As a result of analyses of the individual samples, plotted maps/sections are created for a given core sample and/or a three-dimensional model is made of the core sample for visualization and statistical analysis. Geologists generate this information from several extracted core samples and use it to produce a mineral resource analysis for the geological body. Such an analysis may include the configuration or design of mineral bodies within the overall geological body being investigated, as well as the volume and grade distributions.

Because the physical core samples themselves embody a great deal of information, they serve as a significant resource to the mining operation, particularly for validation and auditing. Mining operations invest considerable resources to store, preserve and make core samples available during a given project and for future ventures. The extracted and analyzed core samples pieces that remain onsite, being central to the mineral resource analysis, are catalogued, physically stored in boxes, and stacked in core farms so that they may be physically accessed repeatedly for further analysis and/or site audits. As for further analysis, often geologists overlook important geological features during a first pass or even a main logging stage of a project or an audit.

Traditionally, if further work with the core samples were to be required, the geologists had to be physically present at the core farm to handle and study the samples in person. Many exploration sites are in remote locations, and it can be expensive and time consuming for geologists to always be present onsite.

In order to reduce some of the effort, time and expense of geologists having to be physically onsite to study core samples, some mining operations have been employing core sample scanners to digitally capture images of core samples. The digital images can then be electronically shared with the geologists in different locations. One example of a commercially-available core sample scanner is the CoreScan 3 offered by the DMT Group. The CoreScan 3, described at the website https://www.dmt-group.com/products/geo-measuring-systems/drill-core-scanner-dmt-corescan/dmt-corescan-3.html, is configured as a tabletop kiosk unit with an open lower table portion and an upper imager portion for imaging objects placed onto the open table portion. The table portion can receive core samples for flat (two-dimensional) scanning of core samples. For three-dimensional scanning, the table portion also includes mechanical rollers that can both support and roll a heavy cylindrical core sample about a horizontal axis while the imager portion captures image data of all sides of the core sample from above. A downstream processing unit is configured with appropriate software for processing the captured image data to create a three-dimensional model of the cylindrical core sample for study and analysis. According to the published specifications of the CoreScan 3, the unit has a length of 1.36 meters, a height of 1.28 meters, and a weight of 128 kilograms.

While the CoreScan 3 is a useful tool, its size and weight limit where and when it can be used. As explained in the publication entitled “A Portable Core Imaging Scanner” (Kofman, Duerksen and Schmitt, University of Alberta, Edmonton, Alberta, Canada—2012), one reason that core imaging has not been more accepted is that the available equipment is relatively bulky such that its use is not usually practical. Research sites are often remote and rugged, potentially limiting the amount and types of equipment that can be brought onsite by investigators for data acquisition and analysis. The Kofman et al. paper proposes a similar, roller-based core sample scanner for receiving horizontally-oriented cylindrical core samples, and offers that constructing such a device using aluminum for some components would provide a superior cost and strength to weight ratio, thereby perhaps making it less difficult to get into the more remote and rugged sites.

The CoreScan 3 and the device proposed by the Kofman et al. paper include several moving parts in order to enable them to physically support and roll core samples for imaging. With high-volume core sample scanning operations, rollers, bearings, motors and other such moving parts exposed to dust, rock fragments and frequent use are of course subject to failure. If a scanner having such parts is required to be moved to a different location, the moving parts are also at risk of being knocked out of alignment. As such, maintenance costs of such physically-complex units can be significant. Furthermore, components such as motors, bearings and rollers suited to physically supporting oftentimes heavy core samples will typically be constructed with steel. They will therefore contribute greatly to overall weight, despite the weight savings from using lighter materials such as aluminum for other components.

In addition, core sample scanners that employ horizontal rollers to support and roll cylindrical core samples during imaging do not easily accommodate non-cylindrical core samples such as the half-cylinder, three-quarter cylinder, or quarter-cylinder samples into which an originally-cylindrical core sample can be divided. As would be understood, rolling a non-cylindrical core sample would result, essentially, in uncontrolled tumbling of the core sample during attempted rotation, making it very difficult to capture images suitable for forming a useful three-dimensional model. Because of this, if a three-dimensional scan of a non-cylindrical core sample is required, the technician using the core sample scanner must get quite involved by manually manipulating the core sample instead of allowing it to tumble freely. This manual manipulation tends to significantly lengthen the scanning time, reducing the efficiency of the overall operation.

Various technologies are offered by other providers, such as the Reflex IQ-logger offered by Imdex Limited of Balcatta, Australia. The Reflex is a handheld, mouse-like, device that can be rolled along the orientation line of a core to record depth and structural measurements using laser alignment, and is designed to be used without removing the core from the tray in which it rests.

U.S. Pat. No. 10,235,760 to Monteiro et al. discloses a device, system and method for capturing digital images of a rock specimen in a region of interest. The device includes an inner chamber having a wall surrounding the region of interest, the chamber having a specimen support structure at the bottom of the region of interest and an open top opposite the specimen support structure, the specimen support structure dimensioned to receive and support an elongate core sample in an upright orientation within the region of interest. The device further includes an imaging system associated with the chamber and comprising multiple digital imaging devices spaced around the region of interest, each digital imaging device oriented to have a respective field of view encompassing the region of interest. The device further includes an illumination system associated with the chamber and switchable between a first illumination state and a second illumination state and comprising a plurality of illumination sources spaced around the region of interest, the illumination sources operable to direct intersecting illumination patterns into the region of interest. The device further includes a control system coordinating the imaging system and the illumination system to capture a first set of digital images during the first illumination state and a second set of images during the second illumination state.

While the Monteiro et al. device and methods are very useful, transportation of electronic devices, small or large, across nation borders and seeking regulatory approval for same, can be a challenging problem. Furthermore, improvements in usability and accuracy are always desirable.

### SUMMARY OF THE DISCLOSURE

In accordance with an aspect, there is provided a structural data logging system comprising: a digital video camera; a display device; at least one user input device; and at least one processor in communication with at least the digital video camera and the display device, and configured to: receive video frames captured by the digital video camera; during receipt of the video frames: display the video frames on the display device; process the video frames to detect at least one predetermined machine-readable code; and in the event that the at least one predetermined machine-readable code is detected: determine a pose of the at least one machine-readable code; receive, using the at least one user input device, one or more user selections corresponding to a respective pixel on the display device; based at least on the pose of the at least one machine-readable code at the time each of the one or more user selection is received, calculate a respective 3D coordinate of a corresponding point within a digital 3D model of an object; and augment the digital 3D model with a respective feature at the 3D coordinate.

In an example, calculating is additionally based on a scale of the at least one predetermined machine-readable code.

In an example, the digital 3D model is a digital 3D model of a cylinder having a length and a radius.

In an example, the at least one processor is configured to receive from a user, using the at least one user input device, at least a value of the radius.

In an example, the at least one processor is further configured to: generate a 2D visual representation of the digital 3D model based on the pose of the at least one machine-readable code at the time of the generating.

In an example, the 2D visual representation of the digital 3D model comprises portions including at least: a wireframe portion representing an envelope of the digital 3D model; and a feature portion representing one or more features of the digital 3D model.

In an example, the portions further comprise: at least one feature label corresponding to a respective feature.

In an example, the at least one processor is further configured to: display the 2D visual representation on the display device.

In an example, the at least one processor is further configured to: display a selected at least one of the portions of the 2D visual representation on the display device responsive to a user instruction received using the at least one user input device.

In an example, the respective feature is a 3D coordinate in the 3D model and the at least one processor is further configured to: associate the 3D coordinate with one or more other 3D coordinates of the digital 3D model determined based on one or more prior user selections using the at least one user input device, thereby to augment the digital 3D model with a respective structure defined by multiple associated 3D coordinates.

In an example, the respective structure is one of: a line defined by at least two associated 3D coordinates representing a structural line; a plane defined by two associated 3D coordinates derived from a major axis of a projected ellipse major axis; and a plane defined by at least three associated 3D coordinates.

In an example, the at least one processor is configured to: receive, using the at least one user input device, first and second user selections corresponding to respective pixels on the display device; based at least on the pose of the at least one machine-readable code at the time the first user selection is received, calculate a respective 3D position of a corresponding first provisional point within the digital 3D model; based at least on the pose of the at least one machine-readable code at the time the second user selection is received, calculate a respective 3D position of a corresponding second provisional point within the digital 3D model; generate a first vector passing through a 3D position of the digital video camera and the first provisional point; generate a second vector passing through a 3D position of the digital video camera and the second provisional point; calculate a respective 3D intersection position of the first vector and the second vector; and augment the digital 3D model with a respective feature at the 3D intersection position.

In an example, the 3D intersection position is one of: a 3D point that is common to both the first vector and the second vector intersect; and a 3D point along the shortest line between the first vector and the second vector.

In an example, the 3D point along the shortest line between the first vector and the second vector is the 3D point at the midpoint of the shortest line between the first vector and the second vector.

In an example, the structural data logging system further comprises: a hand tool having a rigid body defining: an object-receiving surface; and at least one code-presenting surface, wherein the object-receiving surface is dimensioned to interface with a physical object for which structural data is to be logged, and wherein the at least one code-presenting surface presents a respective one of the at least one predetermined machine-readable codes.

In an example, the hand tool is dimensioned to be held by a user against a physical object while the hand tool is within the field of view of the digital video camera.

In an example, the hand tool is dimensioned to be at least temporarily attached to a physical object while the hand tool is within the field of view of the digital video camera.

In an example, the at least one predetermined machine-readable code is/are affixed or attached, at least temporarily, to the object.

In an example, the object-receiving surface is dimensioned to interface with a drill core sample as the object, the object-receiving surface comprising a vertical line for aligning the object-receiving surface with a reference line of the drill core sample, and a horizontal extent for aligning the object-receiving surface with particular positions along the length of the drill core sample.

In an example, the object-receiving surface is dimensioned to interface with drill core samples having a range of radii.

In an example, the at least one processor is configured to: receive from a user, using the at least one user input device, at least a value corresponding to a current position along the length of the drill core sample, wherein re-alignment by a user of the object-receiving surface with a different particular position along the length of the drill core sample corresponds to a different respective position along the length of the 3D digital model.

In an example, the at least one user input device comprises at least one of: a mouse; a keyboard; a touch-sensitive array associated with the display device; a pointed tool with a predetermined machine-readable code captured in the video frames and processeable by the at least one processor to determine a pose of the pointed tool; and an eye-tracking device.

In accordance with another aspect, there is provided a hand tool for a structural data logging system, the hand tool comprising: a rigid body defining: an object-receiving surface; and at least one code-presenting surface, wherein the object-receiving surface is dimensioned to interface with a physical object for which structural data is to be logged, and wherein the at least one code-presenting surface presents a respective one of at least one predetermined machine-readable code, the hand tool dimensioned to be held by a user against a physical object while the hand tool is within the field of view of a digital video camera.

In an example, the object-receiving surface is dimensioned to interface with a drill core sample as the object, the object-receiving surface comprising a vertical line for aligning the object-receiving surface with a top line of the drill core sample, and a horizontal extent for aligning the object-receiving surface with particular positions along the length of the drill core sample.

In an example, the object-receiving surface is dimensioned to interface with drill core samples having a range of radii.

In accordance with another aspect, there is provided a computer-implemented structural data logging method comprising: receiving video frames captured by a digital video camera; during receipt of the video frames: displaying the video frames on a display device; processing the video frames to detect at least one predetermined machine-readable code; in the event that the at least one predetermined machine-readable code is detected: determining a pose of the at least one machine-readable code; receiving, using at least one user input device, one or more user selections corresponding to a respective pixel on the display device; based at least on the pose of the at least one machine-readable code at the time each of the one or more user selection is received, calculating a respective 3D coordinate of a corresponding point within a digital 3D model of an object; and augmenting the digital 3D model with a respective feature at the 3D coordinate.

In accordance with another aspect, there is provided a non-transitory computer readable medium embodying a computer program executable on a computing system for structural logging, the computer program comprising: computer program code for receiving video frames captured by a digital video camera; and computer program code for, during receipt of the video frames: displaying the video frames on a display device; processing the video frames to detect at least one predetermined machine-readable code; in the event that the at least one predetermined machine-readable code is detected: determining a pose of the at least one machine-readable code; receiving, using at least one user input device, one or more user selections corresponding to a respective pixel on the display device; based at least on the pose of the at least one machine-readable code at the time each of the one or more user selection is received, calculating a respective 3D coordinate of a corresponding point within a digital 3D model of an object; and augmenting the digital 3D model with a respective feature at the 3D coordinate.

### BRIEF DESCRIPTION OF THE FIGURES

Examples will now be described with reference to the appended figures, in which:

FIG. 1 is a combined schematic and conceptual diagram of a structural data logging system, according to an example;

FIG. 2 is a flowchart depicting a computer-implemented structural data logging method, according to an example;

FIG. 3 is a schematic diagram showing a hardware architecture of a computing system;

FIG. 4 is a perspective view of a checkerboard pattern for calibrating a digital video camera;

FIG. 5 is a perspective view of a hand tool for use in a structural data logging system for drill core samples, according to an example;

FIG. 6A is a perspective view of a user holding both a cylindrical core sample and the hand tool of FIG. 5 while the core sample is against an object-receiving surface of the hand tool;

FIG. 6B is a view of contents displayed on a screen of a display device as captured by a digital video camera, including the hand tool of FIG. 5 and a 2D representation of a 3D model;

FIG. 7 is another view of the hand tool of FIG. 5 and a 2D representation of a 3D model;

FIG. 8 is another view of the hand tool, not receiving any core sample and therefore in isolation;

FIG. 9 is another view of the hand tool of FIG. 5 and a 2D representation of a 3D model;

FIG. 10A is a front elevation view of the hand tool of FIG. 5;

FIG. 10B is a top plan view of the hand tool of FIG. 5;

FIG. 10C is a side elevation view of the hand tool of FIG. 5;

FIG. 10D is a front perspective view of the hand tool of FIG. 5;

FIG. 10E is a rear perspective view of the hand tool of FIG. 5;

FIGS. 11A-11F depict six different machine-readable codes that may be affixed to respective code-receiving surfaces of the hand tool of FIG. 5;

FIG. 12 is a combined schematic and conceptual diagram of a structural data logging system, according to an example;

FIG. 13 is a combined schematic and conceptual diagram of a structural data logging system, according to an example;

FIG. 14 is a combined schematic and conceptual diagram of a structural data logging system, according to an example;

FIG. 15 is a combined schematic and conceptual diagram of a structural data logging system, according to an example;

FIG. 16 is a combined schematic and conceptual diagram of a structural data logging system, according to an example;

FIG. 17 is a combined schematic and conceptual diagram of a structural data logging system, according to an example;

FIG. 18 is a view of a screen of a display device of a structural logging system during a user selection using a user input device of a first point on the display device during logging of a feature;

FIG. 19 is a view of a screen of a display device of a structural logging system during a user selection using a user input device of a second point on the display device during logging of a feature;

FIG. 20 is a view of a screen of a display device of a structural logging system after a user selection using a user input device of first and second points on the display device for logging of a feature;

FIG. 21 is a view of a screen of a structural logging system, similar to that shown in FIG. 20, but showing labels defining characteristics of a structure logged in association with a 3D model;

FIG. 22 is a view of a screen of a display device of a structural logging system, showing multiple features having been logged in association with a 3D model;

FIGS. 23, 24 and 25 are 2D representations of a digital 3D model, with features logged as in FIG. 22, in different poses as they would be shown on a display device;

FIGS. 26, 27 and 28 are 2D representations of a digital 3D model, with features logged as in FIG. 22, in additional different poses as they would be shown on a display device;

FIG. 29 is a 2D representation of the digital 3D model of FIG. 22 showing conceptually that the 3D coordinates and features may be exported to one or more electronic logging tables for downstream processing;

FIG. 30 is a combined schematic and conceptual diagram of a structural data logging system, according to an example;

FIG. 31 is a combined schematic and conceptual diagram of a structural data logging system, according to an example;

FIG. 32 is a view of the screen of a display device of a structural logging system, showing a wireframe portion of a 2D representation of a digital 3D model of a cylindrical drill core, as well as the actual physical drill core being a three-quarters cylinder, together forming a composite for display;

FIG. 33 is a representation of the digital 3D model of FIG. 32 as would be shown on the screen of a display device, with a user using a user input device to identify a first provisional point on a first vector;

FIG. 34 is a representation of the digital 3D model of FIG. 32 as would be shown on the screen of a display device, with a user using a user input device to identify a second provisional point on a second vector;

FIG. 35A is a top view of a three-quarter drill core sample, an outer envelope of a digital 3D model, and the first provisional point of FIG. 33;

FIG. 35B is a top view of the three-quarter drill core sample, the outer envelope of the digital 3D model, and the second provisional point of FIG. 34;

FIG. 35C is a top view of the three-quarter drill core sample, the outer envelope of the digital 3D model, the first and second provisional points of FIG. 34, and respective vectors intersecting at a point corresponding to the outer surface of the three-quarter drill core sample;

FIG. 36A is a schematic and diagram of a structural data logging system, according to an example;

FIG. 36B is a view of a screen of a display device of the structural logging system of FIG. 36A after a user selection using a pen tool user input device of a 3D point for logging of a feature;

FIG. 37A is a top plan view of the pen tool of FIG. 36B;

FIG. 37B is a front perspective view of the pen tool of FIG. 36B;

FIG. 37C is a distal end view of the pen tool of FIG. 36B;

FIG. 37D is a side elevation view of the pen tool of FIG. 36B; and

FIG. 37E is a rear perspective view of the pen tool of FIG. 36B.

### DETAILED DESCRIPTION

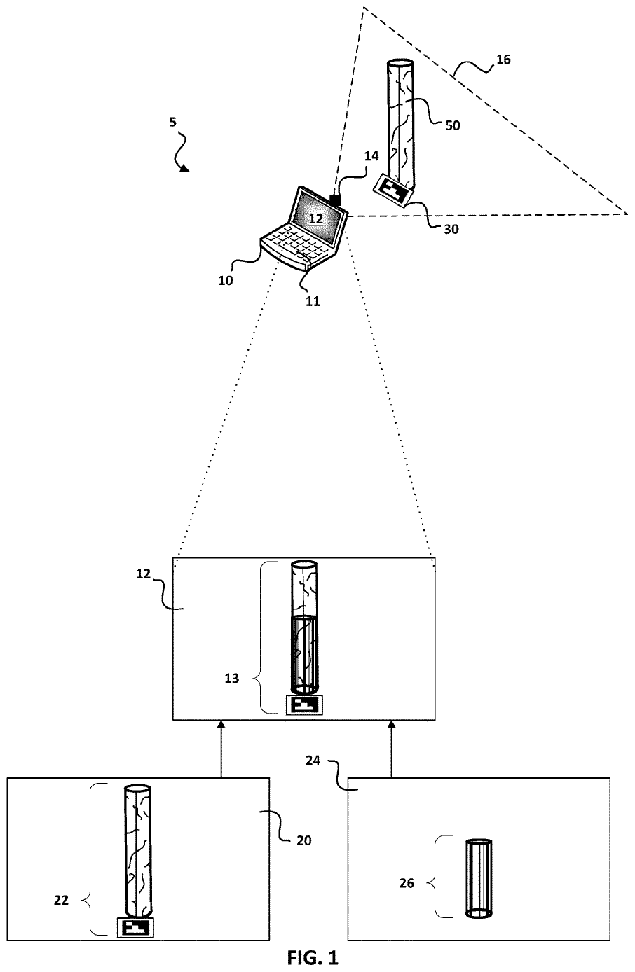

The present application is directed to logging of structure data using computer-implemented methods. FIG. 1 is a combined schematic and conceptual diagram of a structural data logging system 5, according to an example. In this example, system 5 includes a digital video camera 14, a display device 12, and a user input device 11—in this example a computer keyboard. In examples, system 5 also includes another user input device that is a mouse (not shown in FIG. 1). Digital video camera 14, display device 12, and user input devices are integrated as part of the packaging of a laptop computer 10. Laptop computer 10 includes several components as would be known to a person of ordinary skill in general purpose computing, such as at least one processor and system memory, as will be described in further detail below.

However, in this example, the at least one processor is additionally configured as a particular special purpose computer for logging of structure data in a number of ways, as will be described herein. In particular, and as will be described in further detail, the at least one processor is in communication with digital video camera 14, display device 12, and any input devices such as user input device 11, and is configured to receive video frames captured by the digital video camera and, during receipt of the video frames, display the video frames on the display device 12. Furthermore, the at least one processor is configured to process the video frames to detect at least one predetermined machine-readable code, such as code 30, that may have been captured in the region of interest 16 captured within the field of view of digital video camera 14. The at least one processor is also configured to, in the event that the at least one predetermined machine-readable code 30 is detected, determine a pose (i.e., a position and orientation relative to, for example, digital video camera 14) of the at least one machine-readable code 30, and receive, via the at least one user input device such as user input device 11, one or more user selections corresponding to a respective pixel on display device 12. Furthermore, the at least one processor is configured to, based at least on the pose of the at least one machine-readable code 30 at the time each of the one or more user selection is received, calculate a respective 3D coordinate of a corresponding point within a digital 3D model of an object. The at least one processor is also configured to augment the digital 3D model with a respective feature at the 3D coordinate.

System 5 is provided to enable a user to visually register a representation of a digital 3D model of an object that is displayed on display device 12 with a physical object in the region of interest that is captured by digital video camera 14 and displayed in conjunction with the representation of the digital 3D model. As will be explained, the digital 3D model is not anchored to any object in the region of interest 16, except for the at least one predetermined machine-readable code 30. If code 30 is not detected by system 5 in a video frame, then no representation of the digital 3D model is displayed, even if the object 50 to which the digital 3D model is intended to correspond is within the region of interest 16. Furthermore, even if object 50 to which the digital 3D model is intended to correspond is not within region of interest 16, a representation of digital 3D model may be displayed as long as predetermined machine-readable code 30 can be detected within the video frames. The anchoring of the digital 3D model to the predetermined code 30 in this way provides significant easing of processing by system 5 of video frames, because system 5 is required only to detect the predetermined machine readable code 30 and to determine its pose.

Also shown in FIG. 1 is an enlarged representation of what may be viewed in display screen 12 depending on what is found within region of interest 16 and the pose of machine-readable code 30. In FIG. 1, because both an object 50 (in this example, a drill core sample) and code 30 are captured by digital video camera 14, system 5 is able to process code 30 to determine its pose and, based on the pose of code 30, and additionally based on a scale of code 30 as viewed by digital video camera 14, to set the pose/scale of a 2D representation 26 of the digital 3D model for use in overlaying 2D representation 26 atop the content 22 captured by digital video camera 14 (shown in isolation at 20) to produce a composite 13 for display on display device 12. It will be appreciated that, in some implementations, elements 20 and 24 may represent the contents of two different frame buffers that are combined to produce a single frame of video displayed on display device 12.

The predetermined machine-readable code 30 is shown positioned with respect to object 50 —a cylindrical object in this example—so as to align the 2D representation 26 of the digital 3D model—also a cylinder of generally the same radius—with object 50 as viewed through display device 12. A user is thus able to control the pose of 2D representation 26 via control over the pose of code 30 with respect to digital video camera 14. With the user having visually aligned 2D representation 26 with object 50 by having physically aligned code 30 with object 50, the user may enter selections of pixels on display device 12 at locations corresponding in the user's view to actual points on object 50. This may be done using an input device such as user input device 11 while viewing region of interest 16 through display device 12—and have them processed as will be described as 3D coordinates of points on the digital 3D model itself so that the 3D coordinates of points can augment the digital 3D model to provide information in the digital 3D model corresponding to observations the user makes about features of the object 50. In this way, data about the observed structures of object 50 may be collected by a user in an intuitive and accurate way as part of the digital 3D model, and then, if desired, provided downstream in the form of a structural logging table, spreadsheet, or other data store useful for downstream analysis or other processes.

It will be appreciated that technicians, engineers and analysts onsite at a drilling site will very likely require, and will very likely be equipped with general purpose computers equipped in a similar manner to computer 10. In order to provision such personnel with the capabilities described above and further herein, such a general purpose computer may be provisioned as a special purpose computer by downloading and installing software for configuring the at least one processing device of the otherwise general purpose computer to have the unique features and capabilities described herein. Such personnel may be provided with one or more machine-readable codes 30, which may be displayable on a card, hand held tool, affixed in some way to the object 50 if desired, or otherwise made available for physical positioning in particular predefined ways (as will be described) with respect to an object 50 such as a drill core sample. As such, no additional specialized electrical or electronic equipment, or other tools or equipment besides the software for provisioning the at least one process, and the machine readable code(s) 30, need to be transported to a site to provide the useful functionality described herein. As such, system 5 may very readily be put into operation.

Where the object 50 is a drill core sample or other rock specimen, a user may visually study the object 50 including its intrinsic attributes, and use the user input device to mark 3D coordinates onto the digital 3D model of the core sample, for aspects of planes, lines, fold asymmetry, vergence and facing, along with fault kinematics to indicate in which direction a fault had moved. With the digital 3D model having been completed so as to complete a “virtual core”, it may be stored along with other virtual cores in a virtual core library and retrieved for further manipulation and analysis from any network-connected location, such as at a computer station 1000 or a remote device accessible to a geologist, an auditor, an investor etc. The digital 3D model may also be processed to export the feature data to tables, spreadsheets, or other formats suitable for use by geologists, analysts, investors and other stakeholders.

It will be understood that other rock specimens that are not considered elongate core samples, such as hand-sized chunks of rock not extracted by a core driller, may be placed into a region of interest and accordingly captured by a digital video camera and aligned with a corresponding digital 3D model with an “envelope” shaped not as a cylinder, but as some other object. Variations are possible.

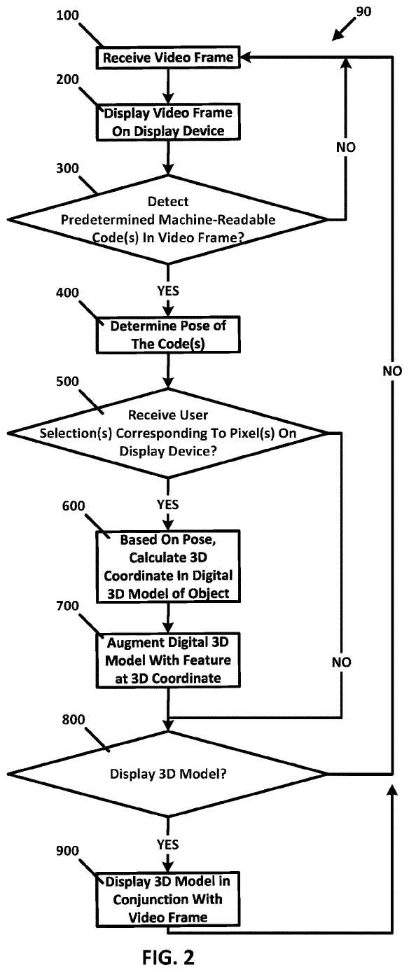

FIG. 2 is a flowchart depicting a computer-implemented structural data logging method 90, according to an example. During method 90, video frames captured by a digital video camera are received (step 100) and during receipt of the video frames, the video frames are displayed on a display device (step 200). The video frames are processed to detect at least one predetermined machine-readable code (step 300). If at step 300 no predetermined machine-readable code is detected in the video frame, the method 90 proceeds to loop back to step 100 to receive and display another video frame on the display device. On the other hand, if a predetermined machine-readable code or codes is detected at step 300, a pose of the machine-readable code(s) is then determined (step 400). Also, it is determined whether one or more user selections corresponding to a respective pixel on the display device is received (step 500). If yes, then based on the pose, a 3D coordinate in a digital 3D model of an object is calculated (step 600) and the digital 3D model is augmented with a feature at the 3D coordinate (step 700). If, at step 600, no user selections corresponding to a respective pixel have been received, then the method skips directly to step 800. At step 800, if the digital 3D model of the object is also to be displayed, a 2D representation of the 3D model (whether augmented as described above or not) is displayed in conjunction with the video frame (step 900). If, at step 800, the digital 3D model is not to be displayed, then the method 90 proceeds to loop back to step 100 to receive and display another video frame on the display device.

In this description, it is regarded as important to conduct a calibration procedure prior to use of the structural logging system, in order to ensure there is a camera model for the digital video camera. In many implementations, the software being used to provision processors of end users' computers to conduct the structural logging steps described herein will be installed on different kinds of computers that are produced by different manufacturers at different times, with different configurations. Even, for example, a digital video camera integrated with one Dell laptop model and a digital video camera integrated with another Dell laptop model, or another of the same Dell laptop model produced during a different year, may have different lenses and other imaging components. Such differences may manifest as different positions, colours, resolutions, of the same region of interest. As such, in this description, an end user may be called upon to conduct a simple calibration procedure to provide the system with information about the intrinsic parameters of the digital video camera that is to be used as part of the structural logging system. It will be appreciated that, where a purpose-built system may be pre-configured prior to delivery, such a calibration may be done at the factory. However, when a user is “bringing his own device” to be provisioned as described herein for structural logging, the user should conduct a calibration procedure to enable the software to know how the user's digital video camera sees a scene.

Some intrinsic parameters include the focal length of the digital cameras, the image sensor format, the principal point and the lens distortion coefficients. The intrinsic parameters may be encoded in one or more matrices usable by the processor to transform pixel values being received thereby to ensure that the digital 3D model of the object is being created and augmented in accordance with the user's expectations. It will also be appreciated that variations between different user computers that may all be used to conduct structural logging for a number of core samples at a given core logging site, need to be eliminated so that the data being logged using different user computers, each potentially with quite different digital video cameras, is “normalized” and thus can be reliably inter-related as overall site data.

In this example, the pose includes a position and orientation, and is used in conjunction with a scale of the at least one predetermined machine-readable code. These aspects of pose may be calculated by identifying the pixel bounds of the code and of certain points within the code, and processing these identified pixels to determine a transform representing position and orientation with respect to the digital video camera as calibrated. It will be appreciated that various methods for determining the pose of a code in a digital video frame are available and may be used for this purpose. Multiple (different) predetermined machine-readable codes may be detected in a given video frame or series of video frames. This may occur in an implementation of a structural logging system according to the present description that requires/supports use of a hand tool or other implement with multiple code-presenting surfaces positioned in a fixed relationship with each other, with more than one of the code-presenting surfaces being within the field of view of the digital video camera at one time. Such an implement may be useful for always, or nearly-always, ensuring that one of the multiple codes can be given a chance to be “seen” by the digital video camera as long as the implement is within its field of view. In this way, a user can have great flexibility to manipulate the implement in whichever way the user feels is appropriate for identifying features of the object and ensuring those features are logged in order to augment the digital 3D model of the object. A user may even occlude part or all of one of the codes that might otherwise be seen, but another unoccluded code or codes may be available to be detected.

In the case of an implement presenting multiple codes, different implementations of detection may be used. For example, multiple of the codes may be detected in sequence or in parallel and the multiple detected codes may be used to disambiguate each other's poses thereby to increase the confidence of the system as compared to only determining the pose of one of the codes. Alternatively, once a first of the codes is detected, the processor may simply use this code for determining pose, and cease looking for, or determining pose of, any other codes that might happen to be present in the video frame being processed. Variations are possible.

In an example, the object itself is a drill core sample rock specimen. Such drill core samples are typically cylindrical in shape due to the manner in which they are extracted from the ground. The radius of a given drill core sample depends on the parameters of the machinery used to extract a drill core sample from the ground. Different predetermined machine-readable codes may be provided for different radii of cylinder, such that upon detection of a particular machine-readable code in a digital video frame the structural logging system may be able to associate that code with a particular radius. In such a situation, a user may simply select an implement having the codes appropriate to the radius of the core sample being studied. However, it may be more useful to provide an implement that is able to interface with core samples of different radii, and to require the user of the system to provide the relevant radius to the one or more processors, for example via a dropdown list presented on a user interface of the computer and/or by typing an amount in a data box on the user interface. The user may also provide information about the core sample, such as its length, an identifier, and other general information about the core sample that may be associated with its corresponding digital 3D model that the user is creating and augmenting. Entry of the radius by the user enables the system to set parameters for the digital 3D model, and to present an appropriate 2D representation of the digital 3D model on the user's display device so that the user can visually confirm that the correct radius of digital 3D model for the core sample being studied is selected.

The system generates a 2D visual representation of the digital 3D model based on the pose of the machine-readable code(s) so that the 2D visual representation may be presented on the display screen in conjunction with the code. Provided the user has positioned the code(s) in the correct predetermined position (such as a reference line or top line of the core sample) with respect to the core sample, the 2D visual representation should be seen by the user, through the display device, to properly align with core sample also being seen through the display device. The user may choose to have the 2D representation displayed, but may choose to hide the 2D representation or portions thereof, for various reasons. This may be toggled ON/OFF by the user via the user interface device 11, for example.

The 2D visual representation may have various different portions that may each be toggled ON/OFF if desired. For example, the 2D visual representation may include a wireframe portion representing an envelope of the digital 3D model. In the case of a cylinder, the wireframe portion may represent the outer bounds of the cylinder of the appropriate radius. The 2D visual representation may include a feature portion representing one or more features of the digital 3D model. Depending on the implementation and the wishes of the user, each of these may be toggled ON/OFF. Different kinds of features, such as line features, may be toggled ON while other kinds of features, such as plane features, may be toggled OFF. Individual features—a specific line—may be toggled ON while other features of the same kind—other lines—may be toggled OFF. Feature labels may be provided enabling a user to label 3D coordinates of points, and/or to label the features of which such points are a part. Such feature labels may also be toggled ON/OFF depending on the implementation and the wishes of the user. Variations are possible.

A given 3D coordinate resulting from a user selection may be associated with at least one other 3D coordinate resulting from another user selection, thereby to form features such as lines and planes. The digital 3D model may be augmented with the features themselves, as well as with the individual 3D coordinates defining the features, such as by enabling a user to name or otherwise characterize the feature.

In examples, a given digital 3D model may have an envelope that represents an “ideal” or “original” condition of the object, where the object being studied at a given time does not exactly match the envelope. For example, a digital 3D model for a drill core sample may have a cylindrical envelope of a particular radius, whereas the drill core sample itself may be a half- or quarter-cylinder, or may have an even more irregular shape. In order for a user to be able to specify 3D coordinates as digital markers at positions in the digital 3D model that correspond with the exterior surface of the actual object but not the envelope of the 3D model, the processor is configured to enable a user to specify two vectors for the desired one 3D coordinate, and to resolve the 3D coordinate as the intersection point of the two vectors, or the closest point in the 3D coordinate system between the two vectors if they are, due to user error or other factors, not actually determined to intersect. This enables the user to specify a point on the surface of the actual object as a point “inside” the envelope of the 3D digital model. The processor can display this inside point and the user can review the placement and determine whether it is satisfactory or otherwise whether it needs adjustment.

To carry this out, in an example, the processor is configured to receive, via the at least one user input device, first and second user selections corresponding to respective pixels on the display device. The processor is also configured to, based at least on the pose of the at least one machine-readable code at the time the first user selection is received, calculate a respective 3D position of a corresponding first provisional point within the digital 3D model. The processor is also configured to, based at least on the pose of the at least one machine-readable code at the time the second user selection is received, calculate a respective 3D position of a corresponding second provisional point within the digital 3D model. The processor is also configured to generate a first vector passing through a 3D position of the digital video camera and the first provisional point. The processor is also configured to generate a second vector passing through a 3D position of the digital video camera and the second provisional point. The processor is also configured to calculate a respective 3D intersection position of the first vector and the second vector. The processor is also configured to augment the digital 3D model with a respective feature at the 3D intersection position.

In examples, the 3D intersection position is a 3D point that is common to both the first vector and the second vector. However, if the first vector and the second vector are not considered to actually mathematically intersect, the system may compensate by calculating the 3D intersection point as a 3D point along the shortest line between the first vector and the second vector. It is contemplated that the 3D intersection point may be any point along this line, depending on how long the line is and other factors. However, it is preferred that the 3D intersection point be calculated as the 3D point at the midpoint of the shortest line between the first vector and the second vector.

In examples, the machine readable code(s) may be positioned at different predetermined positions along the length of the object, such as along the length of a cylindrical drill core sample. Provided the user enters the corresponding position at which the machine readable code is presently positioned, a user may log structures along various core sample regions into the same digital 3D model. As such, if a given core sample is two (2) feet long, a user may begin by positioning the machine readable code near the very bottom of the core sample (at 0.0 feet, for example) to align the bottom of the digital 3D model with the bottom of the core sample so as to capture features for the bottom 0.5-foot extent of the core. After having identified and logged features in this 0.5-foot bottom extent, the user may slide the machine readable code upwards to be positioned at the 0.5-foot position, inform the system of the adjusted position so as to enable logging of structures for the 0.5-foot to 1.0-foot extent. This enables a user to log features for a core sample that is perhaps larger than can be reasonably “seen” within the field of view of the digital video camera, by logging features for sub-portions sequentially.

Various user input devices may be used, such as computer mouse, a computer keyboard, a touch-sensitive array associated with the display device itself, or other user input devices. One contemplated user input device is a pen-based pointer tool having its own machine-readable code viewable by the digital video camera, as described in more detail herein. With such a pointer tool, a user may simply touch features on the actual core sample, and have the position of the pointer tool's machine-readable code determined in a similar manner as has been described herein for the other machine-readable code(s). Such a pointer tool may be an electronic device with a button enabling the user to send a signal when the user wishes for the position of the pointer to be registered as a point. Alternatively, a pointer may simply be non-electronic, equipped with a machine-readable code that the user, by use of another user input device, may send a signal when the user wishes for the position of the pointer to be registered as a point. In one example, it may be useful to equip the processor to detect that the pointer's machine-readable code has been stationary for a predetermined amount of time with respect to the digital 3D model, in order to automatically register its stationary position as a selected point. Variations are possible.

Other user input modes may include eye tracking systems that track the gaze of a user and calculate gaze vectors that can, in turn, be calculated to intersect the digital 3D model at a respective point. A user may therefore simply gaze at an end of a feature on a core sample (or other object whose structural data is being logged) in order to identify that end as a 3D coordinate and then register it as part of the digital 3D model.

It will be appreciated that method 90 has been provided for ease of understanding, and that certain steps in method 90 may be undertaken in parallel. For example, it is contemplated in this description that a particular thread of a processing device, graphics processor or the like may receive each video frame and, perhaps with some processing, direct each video frame to frame buffers for sequential display on the display device. Another processing thread may, in parallel, copy each video frame to a separate area of graphics or system memory to be processed in parallel, for example to process the copy of the frame to search for one or more machine-readable codes and to conduct further processing on the frame copy as described above. Similarly, the receipt of any user selections of pixels (for example, using a mouse) at this time may be detected and processed for augmenting the digital 3D model once it is determined that the one or more machine-readable codes have been detected. It will be appreciated that the digital 3D model may be stored in memory and processed by a different thread to generate a 2D representation of the digital 3D model than may be placed into another frame buffer for combining with/overlaying upon the frame buffer containing the video frame to be displayed, thereby to display the 3D model in conjunction with the video frame (i.e., with the 2D representation being an overlay that replaces corresponding pixels in the video frame with pixels of the 2D representation) if the user has decided to display the 3D model or only parts thereof. A user may choose not to display the digital 3D model (i.e. a 2D representation of the digital 3D model) at all, or may choose to display only portions of the digital 3D model. For example, a user may wish to display a wireframe portion of the digital 3D model, effectively displaying an “envelope” of the object represented by the digital 3D model. A user may wish not to display the wireframe portion and only to display a feature portion, namely features of the 3D model representing structures such as lines, planes, or their constituent points. A user may wish to display both, or neither. Other portions of a 3D model may be provided, and may be displayed or not displayed at the election of a user. Such other portions may include labels for features, labels for 3D coordinates of features, labels for the object, or other kinds of labels. Such labels may each include label identifiers and/or dimensions or dimensional positions, angles and the like, calculated once 3D coordinates have been selected by a user.

A user, perhaps the same user who provided the one or more user selections to identify 3D coordinates of points, or perhaps a different user, may augment a digital 3D model in other ways. For example, a user may retrieve a digital 3D model from a digital library and modify features of the 3D model that had been defined by the user or another user. This might be done by selecting a feature that is already part of the digital 3D model, using a user input device such as user input device 11, and modifying the feature and/or one or more of the 3D coordinates associated with the feature. For example, a user may wish to increase the accuracy of representation of a feature, may wish to label a feature in a different way, may wish to add new features to the 3D digital model, may wish to modify the 3D coordinates that define the feature, and so forth. Furthermore, in the event that the processor has, since creation and augmenting of a particular digital 3D model, been configured with a capability that was not available when the digital 3D model was first created and stored by a user, the user or another user may wish to retrieve the digital 3D model and make use of the capability to further augment the digital 3D model.

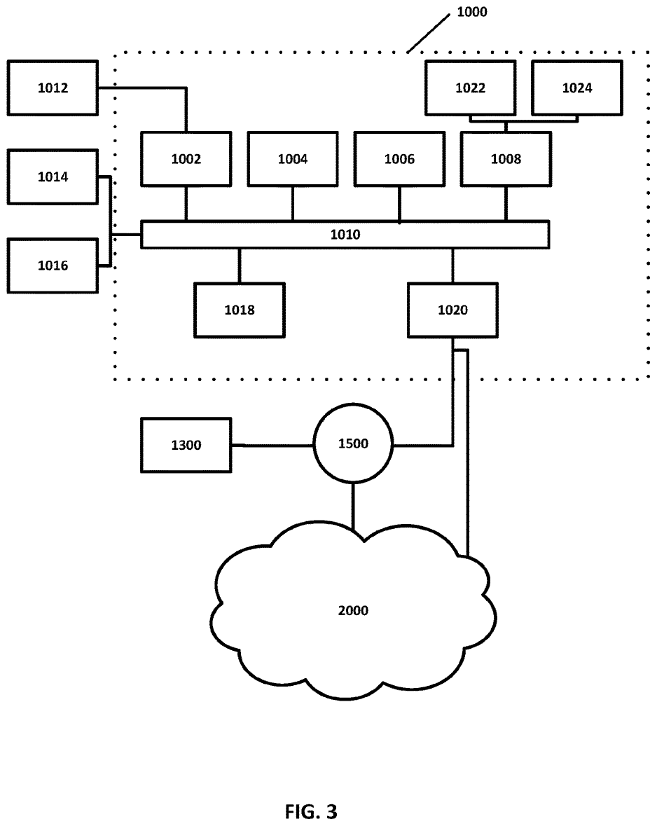

FIG. 3 is a schematic diagram showing a hardware architecture of a computing system 1000. Computing system 1000 is suitable as the hardware platform for computer 5 or for another kind of computing device configured as described herein to carry out structural data logging, including a device such as a smartphone having a video capture device. In this description the term digital image or frame may be used interchangeably to refer to the digital image or frame captured from the video capture device, as well as a data structure representation or copy that may be stored and that contains numbers representing pixels of the captured digital image or frame.

A particular computing system 1000 may be specially configured with software applications and hardware components to enable the capturing, edit, processing, and display of media such as digital video captured by a digital video camera, as well as to encode, decode and/or transcode the digital video according to various selected parameters, thereby to compress, decompress, view and/or manipulate the digital media as desired or required for processing or storage.

Computing system 1000 includes a bus 1010 or other communication mechanism for communicating information, and a processor 1018 coupled with the bus 1010 for processing the information. The computing system 1000 also includes a main memory 1004, such as a random access memory (RAM) or other dynamic storage device (e.g., dynamic RAM (DRAM), static RAM (SRAM), and synchronous DRAM (SDRAM)), coupled to the bus 1010 for storing information and instructions to be executed by processor 1018. In addition, the main memory 1004 may be used for storing temporary variables or other intermediate information during the execution of instructions by the processor 1018. Processor 1018 may include memory structures such as registers for storing such temporary variables or other intermediate information during execution of instructions. The computing system 1000 further includes a read only memory (ROM) 1006 or other static storage device (e.g., programmable ROM (PROM), erasable PROM (EPROM), and electrically erasable PROM (EEPROM)) coupled to the bus 1010 for storing static information and instructions for the processor 1018.

Computing system 1000 also includes a disk controller 1008 coupled to the bus 1010 to control one or more storage devices for storing information and instructions, such as a magnetic hard disk 1022 and/or a solid state drive (SSD) and/or a flash drive, and a removable media drive 1024 (e.g., solid state drive such as USB (Universal Serial Bus) key or external hard drive, floppy disk drive, read-only compact disc drive, read/write compact disc drive, compact disc jukebox, tape drive, and removable magneto-optical drive). The storage devices may be added to the computing system 1000 using an appropriate device interface (e.g., Serial ATA (SATA), peripheral component interconnect (PCI), small computing system interface (SCSI), integrated device electronics (IDE), enhanced-IDE (E-IDE), direct memory access (DMA), ultra-DMA, as well as cloud-based device interfaces).

Computing system 1000 may also include special purpose logic devices (e.g., application specific integrated circuits (ASICs)) or configurable logic devices (e.g., simple programmable logic devices (SPLDs), complex programmable logic devices (CPLDs), and field programmable gate arrays (FPGAs)).

Computing system 1000 also includes a display controller 1002 coupled to the bus 1010 to control a display 1012, such as an LED (light emitting diode) screen, organic LED (OLED) screen, liquid crystal display (LCD) screen or some other device suitable for displaying information to a computer user. In examples, display controller 1002 incorporates a dedicated graphics-processing unit (GPU) for processing mainly graphics-intensive or other parallel operations. Such operations may include rendering by applying texturing, shading and the like to wireframe objects including polygons such as spheres and cubes thereby to relieve processor 1018 of having to undertake such intensive operations at the expense of overall performance of computing system 1000. The GPU may incorporate dedicated graphics memory for storing data generated during its operations, and includes a frame buffer RAM memory for storing processing results as bitmaps to be used to activate pixels of display 1012. The GPU may be instructed to undertake various operations by applications running on computing system 1000 using a graphics-directed application-programming interface (API) such as OpenGL, Direct3D and the like.

Computing system 1000 includes user input devices, such as a keyboard 1014 and a pointing device 1016, for interacting with a computer user and providing information to the processor 1018. The pointing device 1016, for example, may be a mouse, a trackball, or a pointing stick for communicating direction information and command selections to the processor 1018 and for controlling cursor movement on the display 1012. The computing system 1000 may employ a display device that is coupled with an input device, such as a touch-sensitive screen. Other input devices may be employed, such as those that provide data to the computing system via wires or wirelessly, such as gesture detectors including infrared detectors, gyroscopes, accelerometers, other kinds of input devices such as radar/sonar, imaging devices such as front and/or rear digital video and/or still image capture devices such as cameras, infrared sensors, ultrasonic sensors, LiDAR (Light Detection and Ranging) sensors, and other kinds of sensors.

A digital still image and/or digital video device may be integrated in the case of a laptop or desktop computer or other device, or may be a separate device such as a webcam connected to such a computer via a data and/or power cable through a USB or other data/power port, and/or that may wirelessly interact with such a computer, to provide the computer with digital video and images captured by the imaging device.

Computing system 1000 performs a portion or all of the processing steps discussed herein in response to the processor 1018 and/or GPU of display controller 1002 executing one or more sequences of one or more instructions contained in a memory, such as the main memory 1004. Such instructions may be read into the main memory 1004 from another processor readable medium, such as a hard disk 1022 or a removable media drive 1024. One or more processors in a multi-processing arrangement such as computing system 1000 having both a central processing unit and one or more graphics processing unit may also be employed to execute the sequences of instructions contained in main memory 1004 or in dedicated graphics memory of the GPU. In alternative examples, hard-wired circuitry may be used in place of or in combination with software instructions.

As stated above, computing system 1000 includes at least one processor readable medium or memory for holding instructions programmed according to the teachings of the disclosure and for containing data structures, tables, records, or other data described herein. Examples of processor readable media are solid state devices (SSD), flash-based drives, compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of processor readable media, is software for controlling the computing system 1000, for driving a device or devices to perform the functions discussed herein, and for enabling computing system 1000 to interact with a human user (e.g., for controlling mixing of live-streams of audio and video and other media). Such software may include, but is not limited to, device drivers, operating systems, development tools, and applications software. Such processor readable media further includes the computer program product for performing all or a portion (if processing is distributed) of the processing performed discussed herein.

The computer code devices discussed herein may be any interpretable or executable code mechanism, including but not limited to scripts, interpretable programs, dynamic link libraries (DLLs), object-oriented programming (OOP) modules such as classes, and complete executable programs. Moreover, parts of the processing may be distributed for better performance, reliability, and/or cost.

For example, OpenCV (Open Source Computer Vision) and PCL (Point Cloud Library) libraries may be used for image analysis and point cloud generation. A visualization toolkit such as VTK (The Visualization Toolkit), along with QT Enterprise may be used to process the 3D digital model.

Moreover, parts of the processing may be distributed for better performance, reliability, and/or cost.

A processor readable medium providing instructions to a processor 1018 may take many forms, including but not limited to, non-volatile media, volatile media, and transmission media. Non-volatile media includes, for example, optical, magnetic disks, and magneto-optical disks, such as the hard disk 1022 or the removable media drive 1024. Volatile media includes dynamic memory, such as the main memory 1004. Transmission media includes coaxial cables, copper wire and fiber optics, including the wires that make up the bus 1010. Transmission media also may also take the form of acoustic or light waves, such as those generated during radio wave and infrared data communications using various communications protocols.

Various forms of processor readable media may be involved in carrying out one or more sequences of one or more instructions to processor 1018 for execution. For example, the instructions may initially be carried on a magnetic disk of a remote computer. The remote computer can load the instructions for implementing all or a portion of the present disclosure remotely into a dynamic memory and send the instructions over a wired or wireless connection using a modem. A modem local to the computing system 1000 may receive the data via wired Ethernet or wirelessly via Wi-Fi and place the data on the bus 1010. The bus 1010 carries the data to the main memory 1004, from which the processor 1018 retrieves and executes the instructions. The instructions received by the main memory 1004 may optionally be stored on storage device 1022 or 1024 either before or after execution by processor 1018.

Computing system 1000 also includes a communication interface 1020 coupled to the bus 1010. The communication interface 1020 provides a two-way data communication coupling to a network link that is connected to, for example, a local area network (LAN) 1500, or to another communications network 2000 such as the Internet. For example, the communication interface 1020 may be a network interface card to attach to any packet switched LAN. As another example, the communication interface 1020 may be an asymmetric digital subscriber line (ADSL) card, an integrated services digital network (ISDN) card or a modem to provide a data communication connection to a corresponding type of communications line. Wireless links may also be implemented. In any such implementation, the communication interface 1020 sends and receives electrical, electromagnetic or optical signals that carry digital data streams representing various types of information.

The network link typically provides data communication through one or more networks to other data devices, including without limitation to enable the flow of electronic information. For example, the network link may provide a connection to another computer through a local network 1500 (e.g., a LAN) or through equipment operated by a service provider, which provides communication services through a communications network 2000. The local network 1500 and the communications network 2000 use, for example, electrical, electromagnetic, or optical signals that carry digital data streams, and the associated physical layer (e.g., CAT 5 cable, coaxial cable, optical fiber, etc.). The signals through the various networks and the signals on the network link and through the communication interface 1020, which carry the digital data to and from the computing system 1000, may be implemented in baseband signals, or carrier wave based signals. The baseband signals convey the digital data as unmodulated electrical pulses that are descriptive of a stream of digital data bits, where the term “bits” is to be construed broadly to mean symbol, where each symbol conveys at least one or more information bits. The digital data may also be used to modulate a carrier wave, such as with amplitude, phase and/or frequency shift keyed signals that are propagated over a conductive media, or transmitted as electromagnetic waves through a propagation medium. Thus, the digital data may be sent as unmodulated baseband data through a “wired” communication channel and/or sent within a predetermined frequency band, different from baseband, by modulating a carrier wave. The computing system 1000 can transmit and receive data, including program code, through the network(s) 1500 and 2000, the network link and the communication interface 1020. Moreover, the network link may provide a connection through a LAN 1500 to a mobile device 1300 such as a personal digital assistant (PDA) laptop computer, or cellular telephone.

Alternative configurations of computing systems may be used to implement the systems and processes described herein.

Electronic data stores implemented in the database described herein may be one or more of a table, an array, a database, a structured data file, an XML file, or some other functional data store, such as hard disk 1022 or removable media 1024.

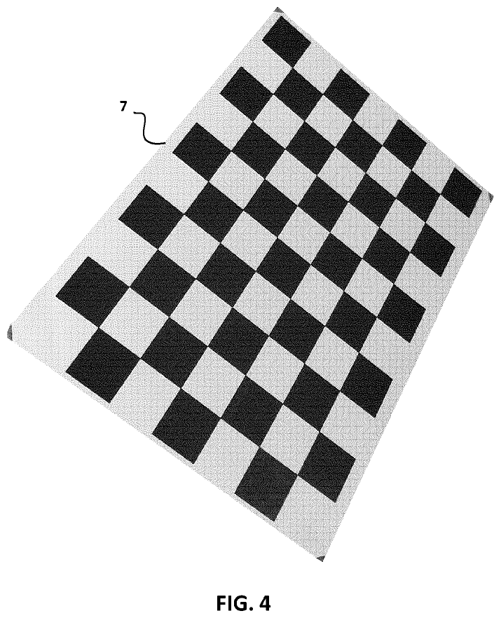

FIG. 4 is a perspective view of a checkerboard pattern that may be useful for calibrating the digital video camera prior to use of the system described herein. Methods of calibrating digital video cameras using checkerboard patterns in order to determine intrinsic parameters, are known.

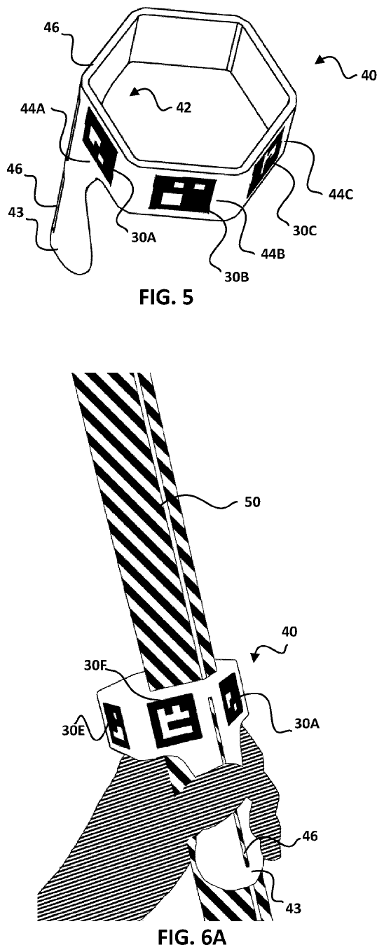

FIG. 5 is a perspective view of a hand tool 40 for use in a structural data logging system for drill core samples, according to an example. In this example hand tool 40 has a handle 43 in a fixed relationship with a rigid body 41. In this example, handle 43 and rigid body are integral. Rigid body 41 defines a fixed relationship between an object-receiving surface 42 and each of multiple code-presenting surfaces 44A, 44B, 44C, 44D, 44E, 44F that each present a respective different machine-readable code 30A, 30B, 30C, 30D, 30E, 30F (referred to collectively herein as machine-readable code 30). In this example, each of machine-readable codes 30A-F may be affixed to a card or sticker that is, in turn, affixed to a respective one of code-presenting surfaces 44A-F. In this example, object-receiving surface 42 is sized to interface with full-cylindrical or part-cylindrical drill core samples of different radii. A line 46 along handle 43 is provided as a window through handle 43 so the user can align line 46 with a reference line marked on a physical drill core sample to be studied. Hand tool 40 is, in this example, dimensioned to be held by the user with the object-receiving surface 42 against—and thus receiving—the drill core sample, at a selected extent along the length of the drill core sample, while hand tool 40, and in particular at least one of machine-readable codes 30A-F, is within the field of view of digital camera 14. In this example, code-presenting surfaces 44A-F are each at a respective position along the outside-facing surface of rigid body 41. At about a 90-degree angle with respect to object-receiving surface, defining an arcuate line (passing through the region 46 in the figure) that can be aligned with a corresponding extent along the length of the drill core sample, in order to register the extent of the digital 3D model with a corresponding extent of the drill core sample itself. Such positioning using line 46 and the arcuate line at the interface between object-receiving surface 42 and code-presenting surface 44, as well as the position/orientation of machine-readable code 30 on code-presenting surface, enables a user to position hand tool 40 in a manner that allows the digital 3D model to correspond in pose with the actual drill core sample (via the pose of the code 30) for the accurate logging of structural data.

FIG. 6A is a perspective view of a user holding both a cylindrical core sample 50 and hand tool 40 while core sample 50 is against the object-receiving surface 42. Through the window shown at line 46, one can see the cylindrical core sample 50 thereby to enable positioning it correctly with respect to hand tool 40. FIG. 6B is a view of contents displayed on a screen of display device 12 (the user's hand is not shown in FIG. 6B so as not to clutter the figure) as captured by the digital video camera 14. Also displayed is a 2D representation 60 of a digital 3D model as generated by the processor based on the pose of hand tool 40 in the video frames as determined by the poses of the machine readable codes 30A-F. It will be appreciated that the digital 3D model, and accordingly its 2D representation, are only “anchored” to machine-readable code 30, and the system has not needed to conduct any processing to make it aware that there is an actual cylindrical object in the field of view of the camera. Because of this, processing of each video frame can be simplified as compared with other solutions, because processing need only identify a machine-readable code such as code 30, and calculate its pose, before then presenting 2D representation 60 accordingly as a correctly-posed overlay. To be serious about logging structural data, a user simply has to ensure that the machine-readable code 30 is positioned correctly with respect to the actual drill core sample as logging is being done.

FIG. 7 is another view of hand tool 40 and 2D representation 60. In this figure also, hand tool 40 is partway along the extent of the drill core sample and, as system 5 has been informed of this, system 5 can present 2D representation accordingly as extending similarly with respect to hand tool 40 as the cylindrical core sample 50 is extending with respect to hand tool 40.

FIG. 8 is another view of hand tool 40, not receiving any core sample and therefore in isolation. FIG. 9 is another view of hand tool 40 and 2D representation 60. It will be appreciated that FIGS. 7 through 9 are intended to show the physical relationships between the code-presenting surfaces 44A-F, the object-receiving surface 42, and the handle 43 of hand tool 40.

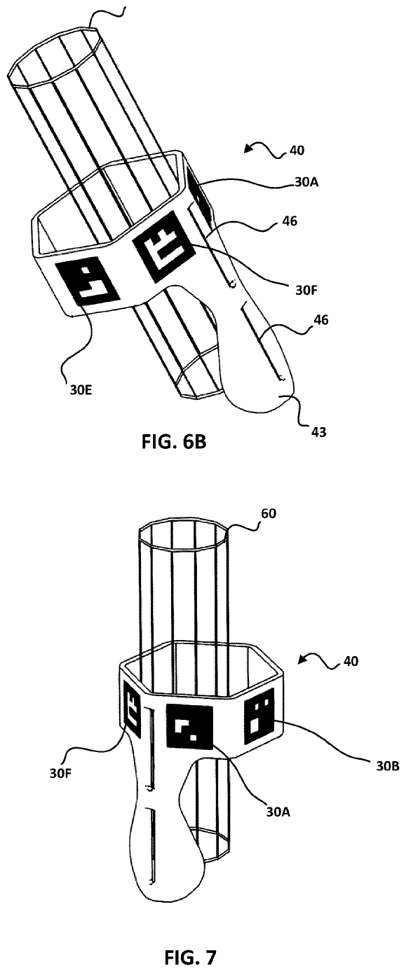

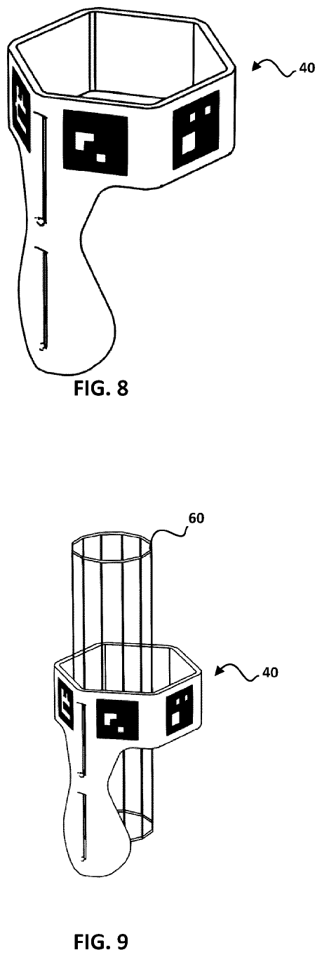

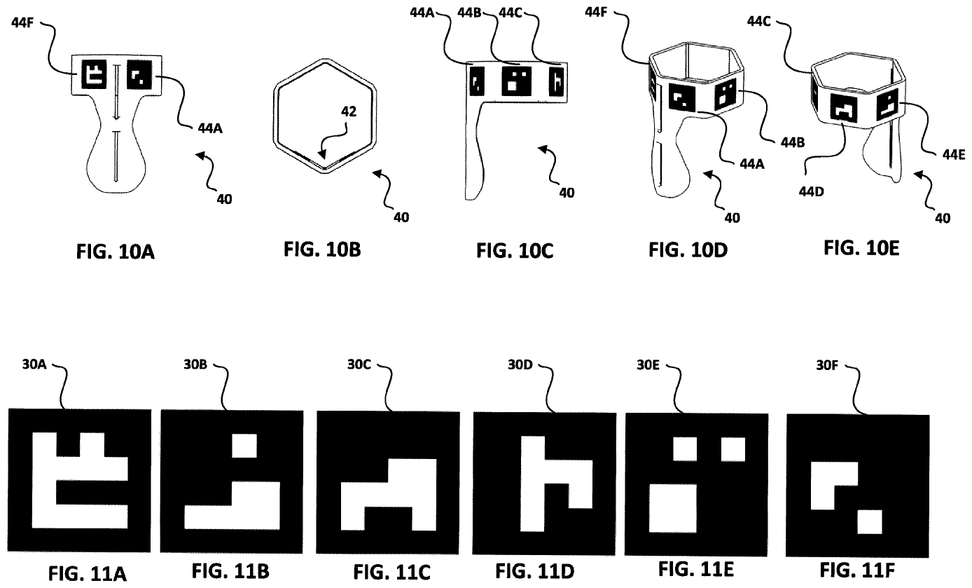

FIG. 10A is a front elevation view, FIG. 10B is a top plan view, FIG. 10C is a side elevation view, FIG. 10D is a front perspective view, and FIG. 10E is a rear perspective view, of hand tool 40 in isolation and indicating the code-presenting surfaces 44A-F as well as the machine-readable codes 30A-F positioned respectively thereon.

FIGS. 11A-11F depict six (6) different machine-readable codes 30A-F that may be affixed to respective code-receiving surfaces 44A-F of hand tool 40. Having different codes on different surfaces provides an opportunity for at least one of the codes to be seen at all times (provided hand tool 40 itself is within the field of view of digital video camera 14) no matter the orientation or position of the hand tool. That is, for example, a particular machine-readable code 30A on a first code-receiving surface 44A may, if code-receiving surface 44A is turned away from digital video camera 14, not be captured in video frames. However, another machine-readable code 30D on code-receiving surface 44D will likely, due to the configuration of hand tool 40, be visible and available for processing to determine pose. Furthermore, in many poses of hand tool 40, multiple of the code-presenting surfaces 44A-F, and thus multiple of the machine-readable codes 30A-F, may be captured in a video frame simultaneously, providing the opportunity for disambiguation or fault tolerance in the event that any one of the machine-readable codes 30A-F is occluded by the user, is temporarily out of the field of view, or for some other reason is not processable. It will be appreciated that machine-readable codes 30A-F should all be distinguishable from each other by the system as unique, unless there is some other feature of hand tool that can be used by the system to disambiguate the codes. For example, the position of handle 43 in conjunction with the machine-readable codes 30A-F may be used to disambiguate pose of hand held tool 40.

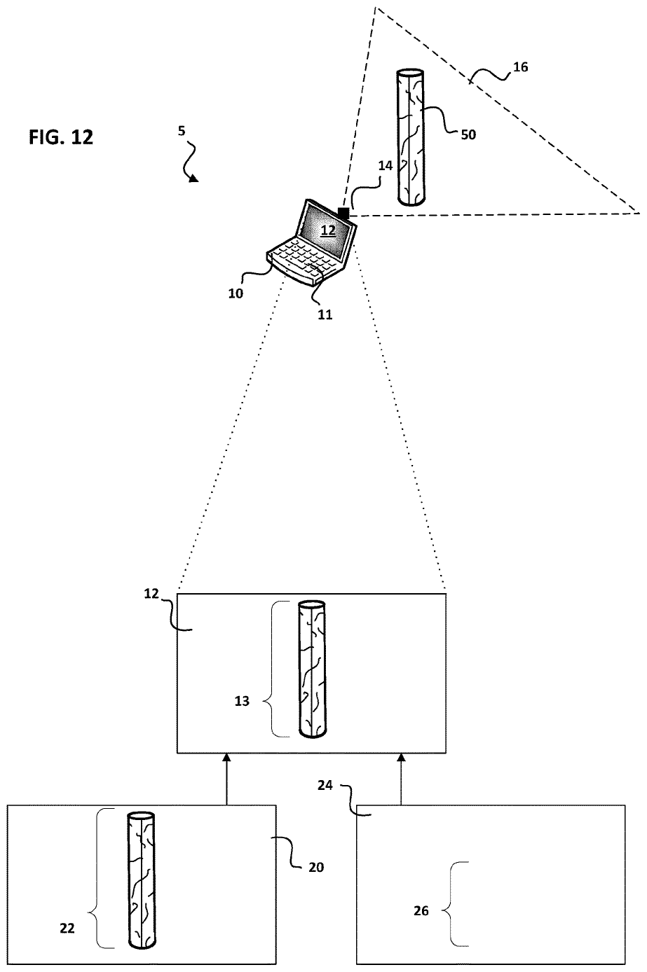

FIG. 12 is a combined schematic and conceptual diagram of system 5 and object 50 (in this figure a drill core sample), but absent any machine-readable code 30 recognizable by system 5. That is, in a state in which no machine-readable code 30 has been detected in a video frame captured by digital video camera 14, system 5 will not present any 2D representation of a 3D model on display device 12 in conjunction with the contents captured in the video frames. Shown in FIG. 12 is an enlarged representation of what may be viewed in display screen 12 depending on what is found within region of interest 16, absent the presence of machine-readable code 30. In FIG. 12, because object 50 but not any machine-readable code 30 is captured by digital video camera 14, system 5 provides nothing visible in terms of a representation 26 in element 24, such that composite 13 being displayed on display device 12, as a combination of content 22 and content 24, appears as though it is just content 22.

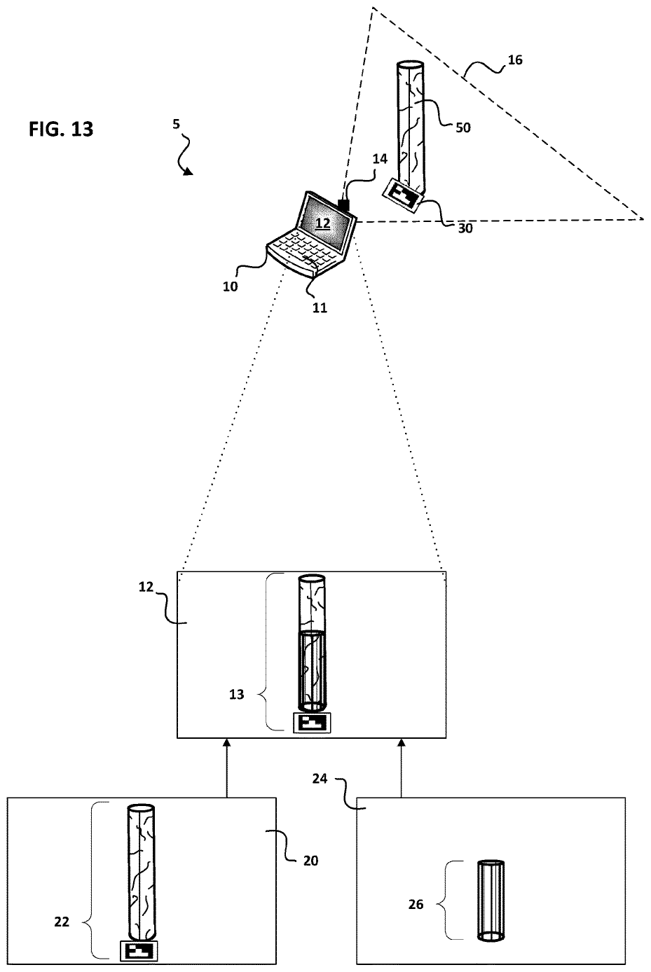

FIG. 13 is a combined schematic and conceptual diagram of system 5, according to an example. Similar to FIG. 1, in a state in which machine-readable code 30 has been detected in a video frame captured by digital video camera 14, system 5 presents 2D representation 26 of the 3D model on display device 12 in conjunction with the contents 22 captured in the video frame. In this figure, 2D representation 26 is depicted as a wireframe cylinder. Because machine-readable code 30 has been physically aligned by a user properly with respect to object 50—a drill core sample—2D representation 26 is seen to “line up” with the drill core sample on display device 12 when elements 20 and 24 are displayed together to produce the composite 13 for display on display device 12.

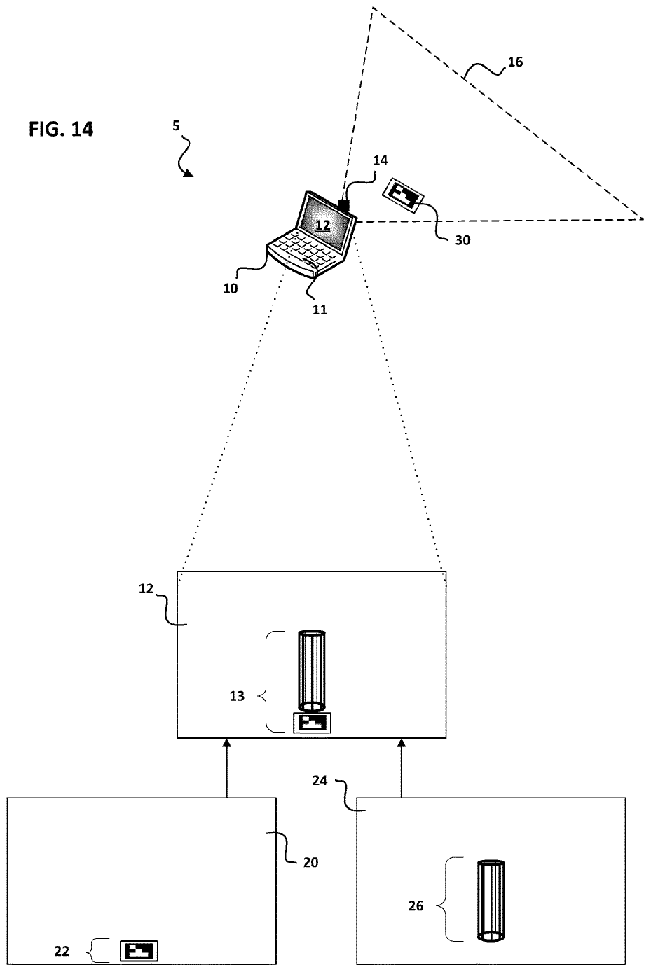

FIG. 14 is a combined schematic and conceptual diagram of system 5, according to an example. In this state, machine-readable code 30 has been detected in a video frame captured by digital video camera 14. Because of this, system 5 presents 2D representation 26 of the 3D model on display device 14 in conjunction with the contents 22 captured in the video frame. However, it will be observed that there is no actual physical drill core sample being captured in the video frame. Despite this, because machine-readable code 30 has been captured in the video frame, 2D representation 26 is depicted as a wireframe cylinder. This figure is provided to demonstrate that 2D representation 26 is anchored to machine-readable code 30 as captured in the video frame, and not to any other feature captured in the video frame. As explained above, by focusing detection and pose calculation on the machine-readable code(s), and away from what may be much more richly-detailed content captured in a video frame, the system is able to process the video frames very efficiently, leading to low latency and low processing consumption compared to alternative approaches.

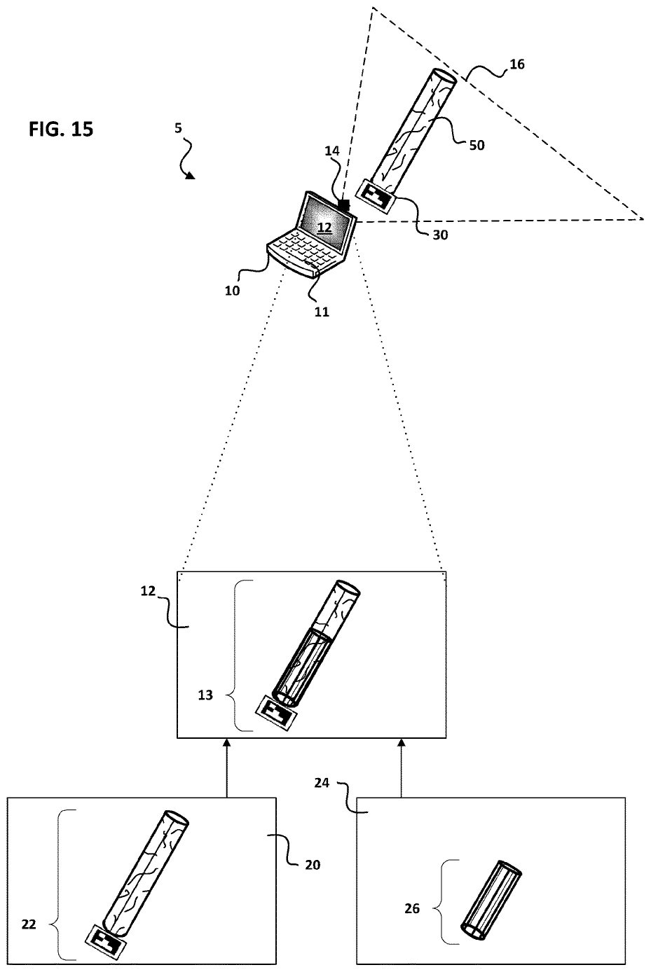

FIG. 15 is a combined schematic and conceptual diagram of system 5, according to an example. In this state, machine-readable code 30 has been detected in a video frame captured by digital video camera 14. Because of this, system 5 presents 2D representation 26 of the 3D model on display device 14 in conjunction with the contents 22 captured in the video frame. In this figure, 2D representation 26 is depicted as a wireframe cylinder, and both machine-readable code 30 and object 50—a drill core sample—are together but in a different pose than that shown in FIG. 13. Because machine-readable code 30 has been physically aligned by a user properly with respect to the drill core sample, 2D representation 26 is seen to “line up” with the drill core sample on display device 12 when elements 20 and 24 are displayed together to produce the composite 13 for display on display device 12, even in the different pose.

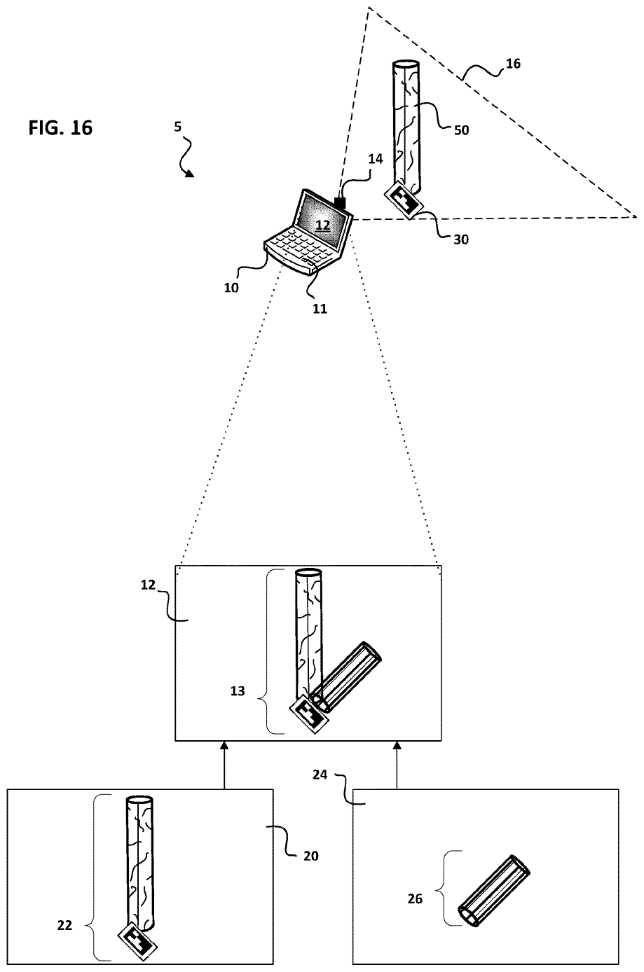

FIG. 16 is a combined schematic and conceptual diagram of system 5, according to an example. In this state, machine-readable code 30 has been detected in a video frame captured by digital video camera 14. Because of this, system 5 presents 2D representation 26 of the 3D model on display device 14 in conjunction with contents 22 captured in the video frame. In this figure, 2D representation 26 is depicted as a wireframe cylinder, but machine-readable code 30 and object 50—a drill core sample are not being positioned by a user in proper position with respect to each other. In particular, machine-readable code 30 is in a pose similar to that shown in FIG. 15, but the drill core sample is itself in a pose similar to that shown in FIG. 13. Because machine-readable code 30 has not been physically aligned by a user properly with respect to the drill core sample, 2D representation 26 is seen to be “misaligned” with the drill core sample on display device 12. Because machine-readable code 30 has not been physically aligned by a user properly with respect to the drill core sample, 2D representation 26 is not seen to “line up” with the drill core sample on display device 12 when elements 20 and 24 are displayed together to produce the composite 13 for display on display device 12. Furthermore, because of the misalignment, should a user attempt to log structural features on the displayed drill core sample using input device 11, such logged features will relate to the 3D model in a manner that is not correlated with how the actual features relate to the physical drill core sample as a whole, thus creating invalid logging data for that drill core sample.

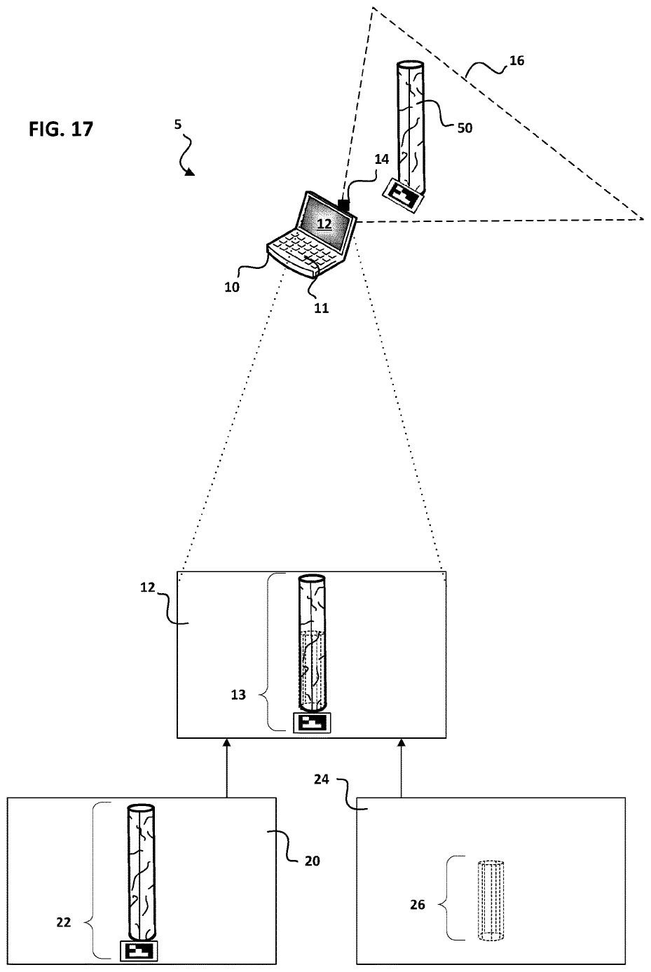

FIG. 17 is a combined schematic and conceptual diagram of system 5, according to an example. Similar to FIG. 13, system 5 is in a state in which machine-readable code 30 has been detected in a video frame captured by digital video camera 14. However, due to a preference selection by the user via user interface 11, system 5 in turn does not present 2D representation 26 of the 3D model on display device 12 in conjunction with the contents 22 captured in the video frame. In this figure, 2D representation 26 is depicted in dashed lines only to show for the reader of this description that the 3D model is aligned with the object 50, even though this wireframe portion is selected by the user at this time not to itself be displayed. However, because machine-readable code 30 has been physically aligned by a user properly with respect to object 50—a drill core sample—then should a user attempt to log structural features using input device 11, such logged features will relate to the 3D model in a manner that is indeed correlated with how the actual features relate to the physical drill core sample as a whole, thus creating valid logging data for that drill core sample. A user may choose to have the wireframe portion displayed during initial engagement of the hand tool with the drill core sample, but thereafter switch it off so that only the subsequently logged features themselves are displayed, as will be described. A user may generally switch the wireframe portion on or off as desired.

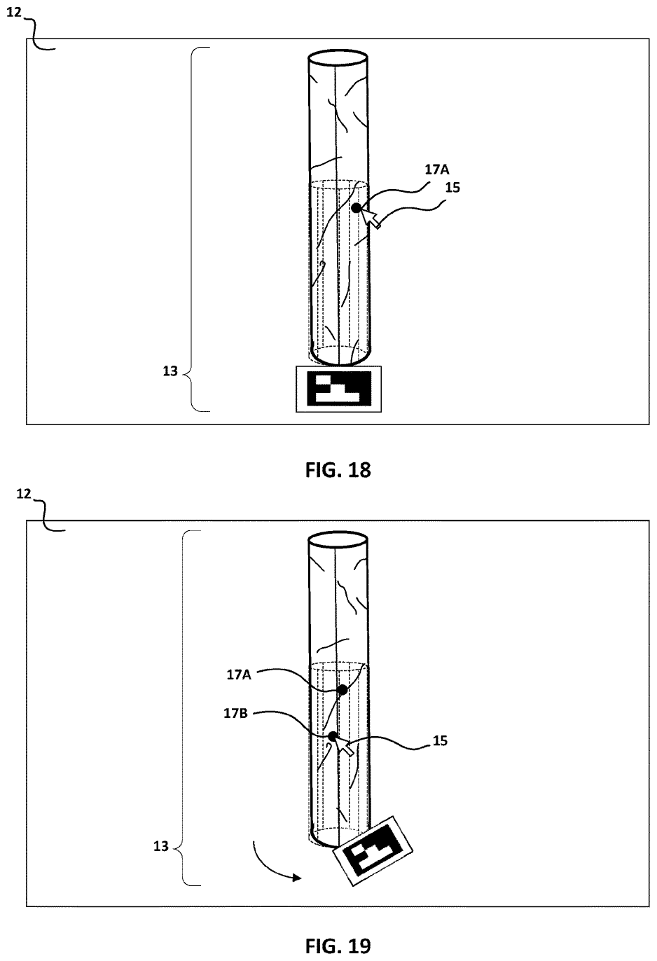

FIG. 18 is a view of a screen of display device 12 of system 5 during a user selection using a user input device of a first point 17A on display device 12 during logging of a feature. In this figure, it can be seen that the digital 3D model “lines up” with the drill core sample as shown in FIG. 17, even though the wireframe portion is not being displayed to the user at the moment (i.e., it is shown in the figure in a dashed line just for ease of understanding). The user may use his/her user input device, in this figure a mouse (not shown) having an onscreen pointer 15, to identify first point 17A on display device 12 that can thereafter be used, based on calibration of camera 14, to define a 3D coordinate for a feature in the 3D model.

FIG. 19 is a view of a screen of display device 12 of system 5 during a user selection using a user input device of a second point 17B on display device 12 during logging of a feature. In this figure, it can be seen that the digital 3D model “lines up” with the drill core sample as shown in FIG. 17, even though the wireframe portion is not being displayed to the user at the moment (i.e., it is shown in the figure in a dashed line just for ease of understanding). The user may use his/her user input device, in this figure a mouse (not shown) having onscreen pointer 15, to identify second point 17B on display device 12 that can thereafter be used, based on calibration of camera 14, to define a 3D coordinate for a feature in the 3D model. It can also be seen that the user, as explained in connection with previous figures, has physically rotated the drill core sample and machine-readable code 30 together as a single “unit”, in order to correspondingly rotate the 3D model so that identification of second point 17B on another part of the surface of the drill core sample can accurately be used to specify the correct 3D coordinate in the digital 3D model.

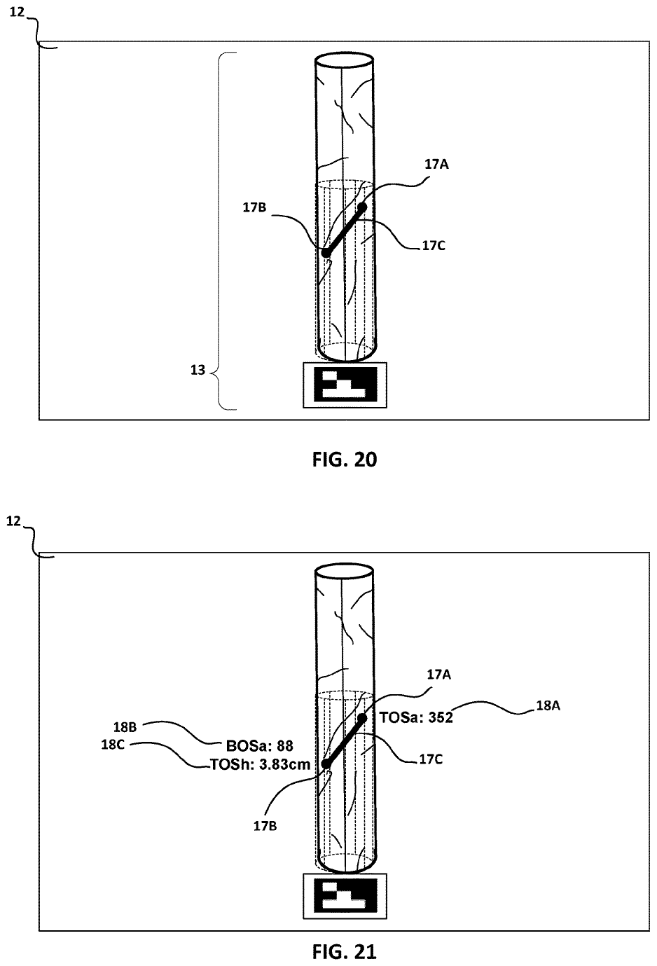

FIG. 20 is a view of a screen of display device 12 of system 5 after selection of the first point 17A and second point 17B in FIGS. 18 and 19. These selected points 17A, 17B have been used to calculate 3D coordinates, and in turn the 3D coordinates have been connected as different points along a single feature, in this case a line 17C through the drill core sample.

FIG. 21 is a view of a screen of the system, similar to FIG. 20, but showing labels defining the line 17C (or “structure”, as used in drill core logging), including a “Top Of Structure” angle TOSa (label 18A) of 352 degrees, a “Bottom of Structure” angle BOSa (label 18B) of 88 degrees, and a “Top of Structure” height TOSh (label 18C) of 3.83 centimetres (cm). It will be appreciated that 3D coordinates, and features 17A, 17B, 17C defined by them, may be represented as such in a Cartesian coordinate system framework, a cylindrical coordinate system framework, or some other coordinate system framework. Each of these angles and heights may be automatically calculated based on the calibration of the digital video camera 14, a radius chosen by the user, and the extent of the machine-readable code 30 along the length of the drill core sample. Even though such calculations may be conducted by the processor, a user may choose whether or not to actually display labels 18A, 18B, and 18C on display device 12 during use.

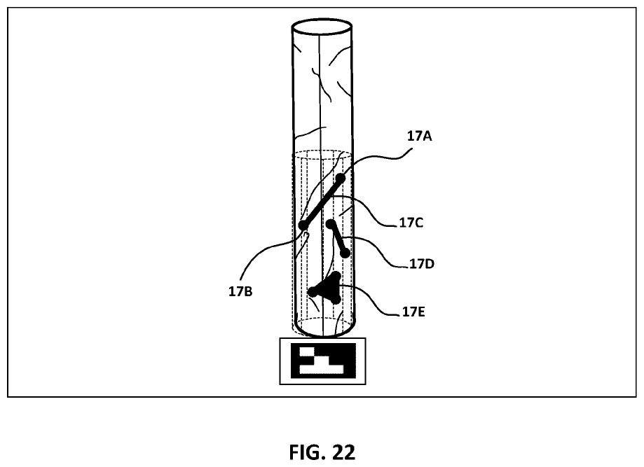

FIG. 22 is a view of a screen of display device 12 of system 5, showing multiple features (a line 17C logged using two 3D points 17A, 17B; another line 17D logged using two respective 3D points; and a plane 17E logged using at least three respective 3D points) having been logged as described herein thereby to augment the digital 3D model of the corresponding drill core sample.

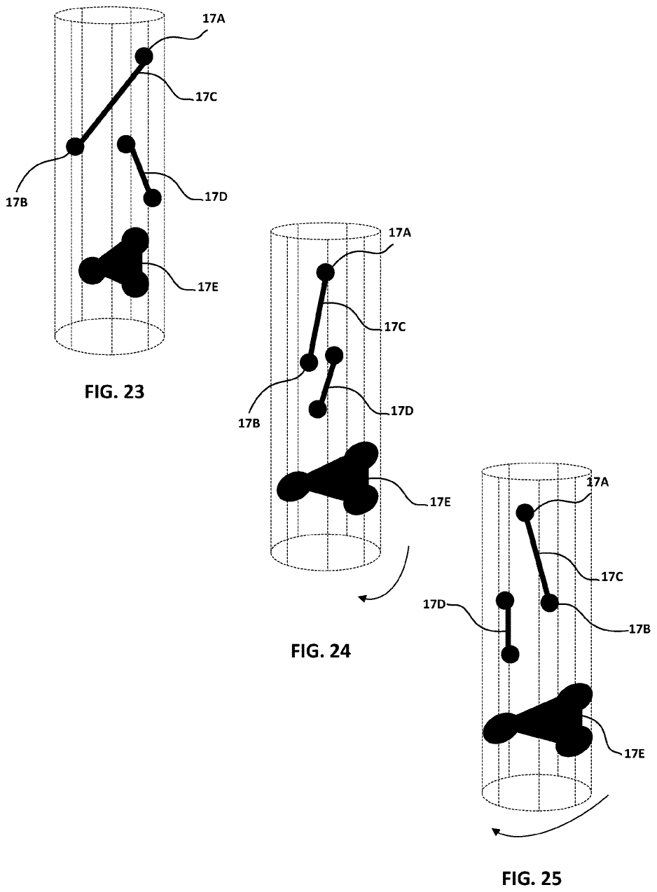

FIGS. 23, 24 and 25 are 2D representations of the digital 3D model of FIG. 22 in different poses as they would be shown on display device 12, showing that as the wireframe portion of the digital 3D model is re-posed as a result of the re-posing by a user of machine-readable code 30 with respect to camera 14, the individual features (17A-E) being part of the digital 3D model are also accordingly re-posed providing the correct impression to a user that the features 17A-E are anchored to the wireframe portion and confirmation that the features are correctly defined. That is, that they correlate correctly to the actual features in the physical drill core sample.

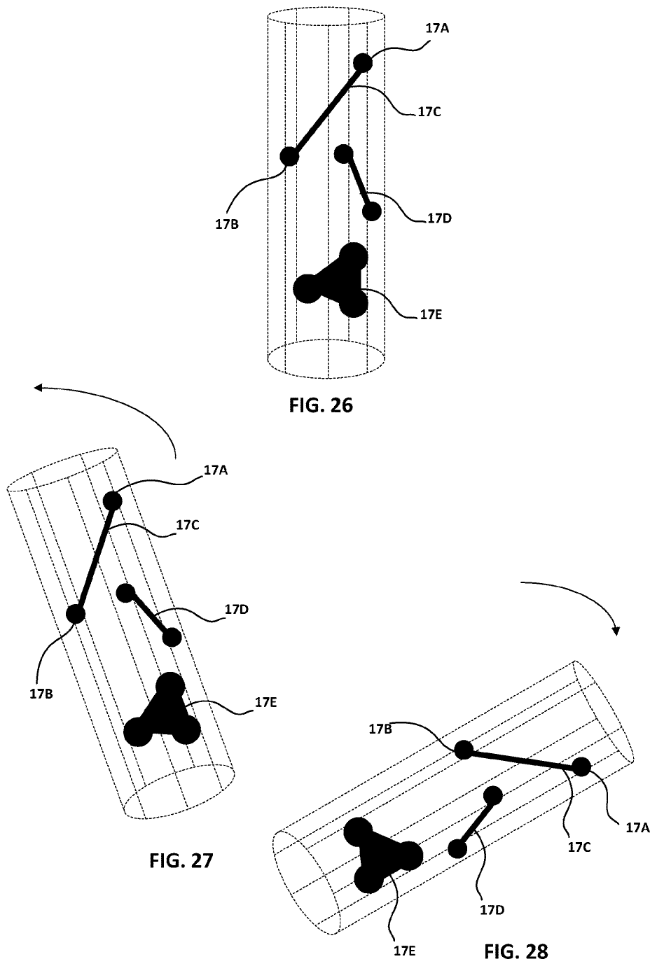

FIGS. 26, 27 and 28 are representations of the digital 3D model of FIG. 22 in further different poses as they would be shown on display device 12, again showing that as the wireframe portion of the digital 3D model is re-posed as a result of the re-posing by a user of machine-readable code 30 with respect to camera 14, the individual features (17A-E) being part of the digital 3D model are also accordingly re-posed providing the correct impression to a user that the features 17A-E are anchored to the wireframe portion and confirmation that the features are correctly defined. That is, that they correlate correctly to the actual features in the physical drill core sample.

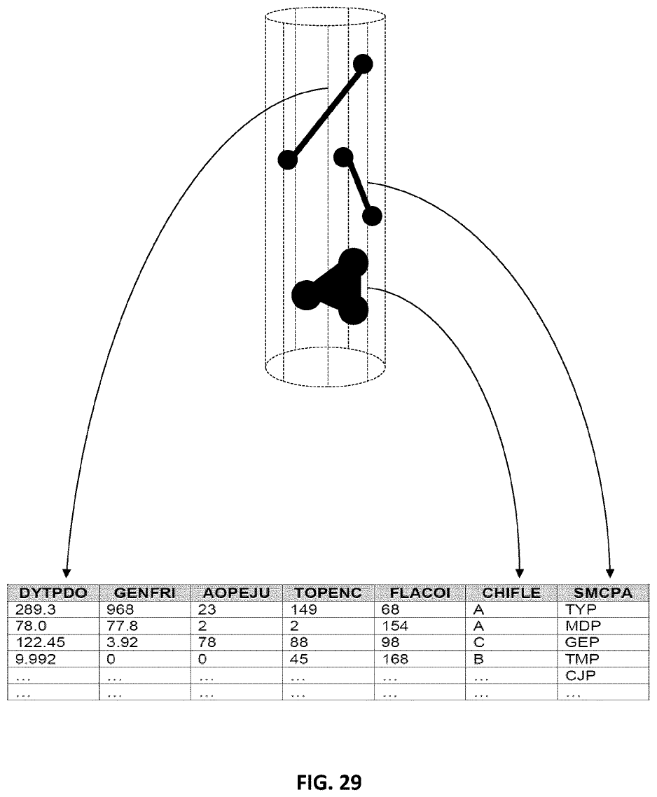

FIG. 29 is a 2D representation of the digital 3D model of FIG. 22 showing conceptually that the 3D coordinates and features defined as described herein may be exported to one or more electronic logging tables for downstream processing by processors for analysis, visualizations, and the like.

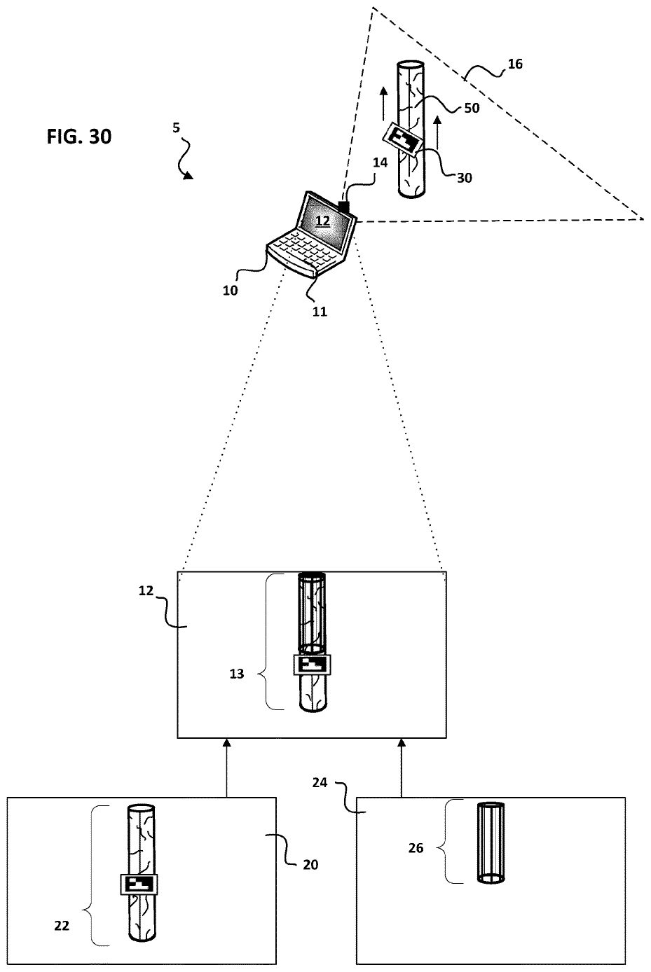

FIG. 30 is a combined schematic and conceptual diagram of system 5, according to an example. Similar to FIG. 13, in a state in which a machine-readable code 30 has been detected in a video frame captured by digital video camera 14, system 5 presents 2D representation 26 of the 3D model on display device 12 in conjunction with the contents 22 captured in the video frame. In this figure, 2D representation 26 is depicted as a wireframe cylinder. Because machine-readable code 30 has been physically aligned by a user properly with respect to object 50—a drill core sample—2D representation 26 is seen to “line up” with the drill core sample on display device 12 when elements 20 and 24 are displayed together to produce the composite 13 for display on display device 12. In this diagram, in contrast to FIG. 13, machine-readable code 30 has been moved “up” the drill core sample and is otherwise properly aligned with the drill core sample. This causes the 3D model, and indeed 2D representation 26 of the 3D model, to be moved upwards along the drill core sample as seen through display device 12. A user may therefore log features of a different segment of the drill core sample. A user should provide input to system 5, via user input device 11 for example, to register that machine-readable code 30 is being moved to a different position along the same drill core sample, so as not to inadvertently log features/structures of one segment as though they were features/structures of another different segment.

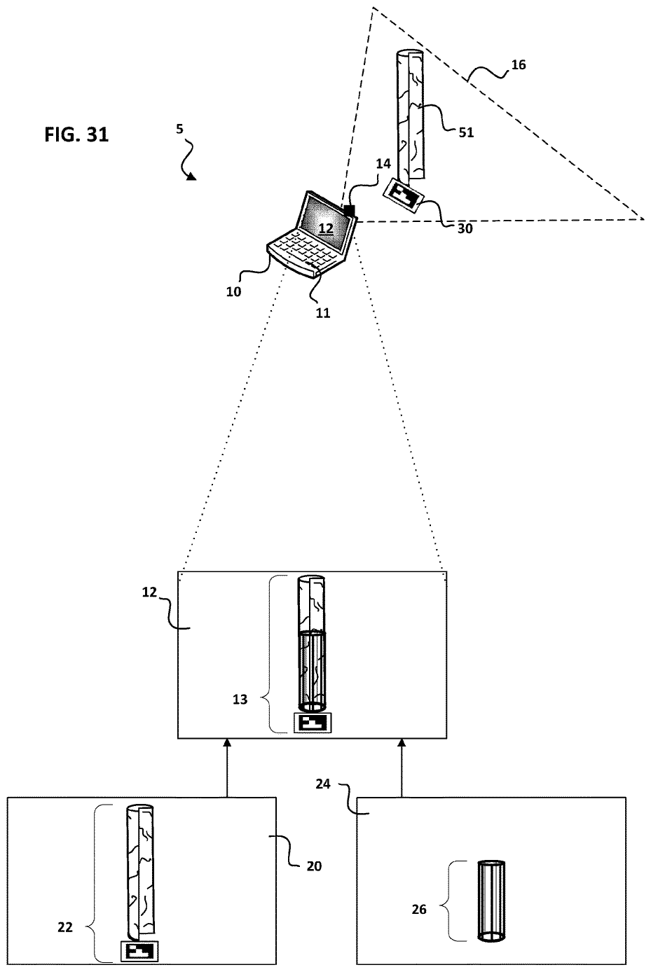

The systems described and depicted herein may be used with objects that do not fulfill the entire envelope of the digital 3D model that is being used for logging of structure features. FIG. 31 is a combined schematic and conceptual diagram system 5 according to an example. Similar to FIG. 1, in a state in which machine-readable code 30 has been detected in a video frame captured by digital video camera 14, system 5 presents 2D representation 26 of the 3D model on display device 12 in conjunction with the contents 22 captured in the video frame. In this figure, 2D representation 26 is depicted as a wireframe cylinder. Because machine-readable code 30 has been physically aligned by a user properly with respect to object 51—a three-quarter drill core sample—2D representation 26 is seen to “line up” with the three-quarter drill core sample on display device 12 when elements 20 and 24 are displayed together to produce the composite 13 for display on display device 12.

As object 51 is a three-quarter drill core sample, it is not a full cylinder. It will be appreciated that a given (full cylinder) drill core sample may be divided into quarters, halves or other portions so that the different divided portions of the drill core sample may be used for different analysis or assay purposes. Furthermore, a given drill core sample may break or crumble, such that at the time of analysis using system such as that described herein, it is not a perfect cylinder. Because a user may wish to identify 3D coordinates and features that appear on the exterior of an incomplete or imperfect cylinder, in an example the processor is configured to enable a user to define a single 3D coordinate by picking two different points along two different vectors that the user judges will intersect at the 3D coordinate “within” the envelope of the digital 3D model, as will be described.

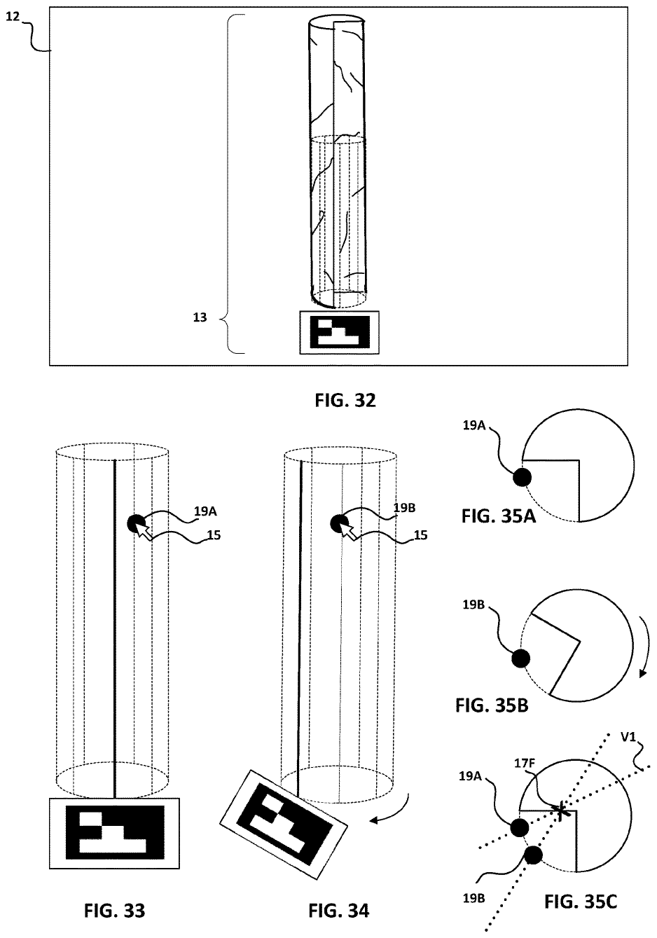

FIG. 32 is a view of the screen of display device 12 of system 5, showing a wireframe portion of a 2D representation of a digital 3D model of a cylindrical drill core, as well as the actual physical drill core being a three-quarters cylinder, together forming a composite 13 as described herein.

FIG. 33 is a representation of the digital 3D model of FIG. 32 as would be shown on the screen of display device 12, with a user using a user input device (in this example, a mouse having onscreen pointer 15) to identify a first provisional point 19A on a first vector V1. The 3D location of the first provisional point 19A and the 3D location of the digital video camera 14 define first vector V1. FIG. 34 is a representation of the digital 3D model of FIG. 32 as would be shown on the screen of display device 12, with a user having rotated the machine-readable code 30 (along with the drill core sample) and having used the user input device (the mouse having onscreen pointer 15) to identify a second provisional point 19B on a second vector V2. The 3D location of second provisional point 19B and the 3D location of the digital video camera 14 define second vector V2. With the first and second vectors V1, V2 having been defined, the system may calculate a 3D coordinate of the intersection point of first and second vectors V2 (or, infer a 3D coordinate based on closest location between first and second vectors V1, V2), thereby to establish the 3D coordinate of a feature point 17F on the surface of the three-quarter drill core sample that the user intended to log.

FIG. 35A is a top view of the three-quarter drill core sample (in solid lines), the outer (circular) envelope of the digital 3D model (in dashed lines), and first provisional point 19A. FIG. 35B is a top view of the three-quarter drill core sample (in solid lines), the outer (circular) envelope of the digital 3D model (in dashed lines), and second provisional point 19B. FIG. 35C is a top view of the three-quarter drill core sample (in solid lines), the outer (circular) envelope of the digital 3D model (in dashed lines), first and second vectors V1, V2 (in dotted lines) each extending from the camera through a respective one of the first and second provisional points 19A, 19B, and the intersection point of first and second vectors V1, V2 (shown also as an “X”) that will serve as the 3D coordinate of the feature point 17F the user intended to mark for a feature. It will be appreciated that the defining of an intersection point of vectors V1, V2 may be conducted by placing system 5 in a mode for dealing with objects that do not fulfill the entire envelope of the 3D model (such as a three-quarter cylinder core sample in a 3D model of a full cylinder) in which it can recognize that points 19A, 19B are not themselves intended to correspond one-to-one with actual feature points on the surface of the physical core sample and thus themselves added to the 3D model, but are instead intended to, as set forth above, be provisional points that one registered can themselves be processed together along with the 3D location of camera 14 in order to define such a feature point 17F.

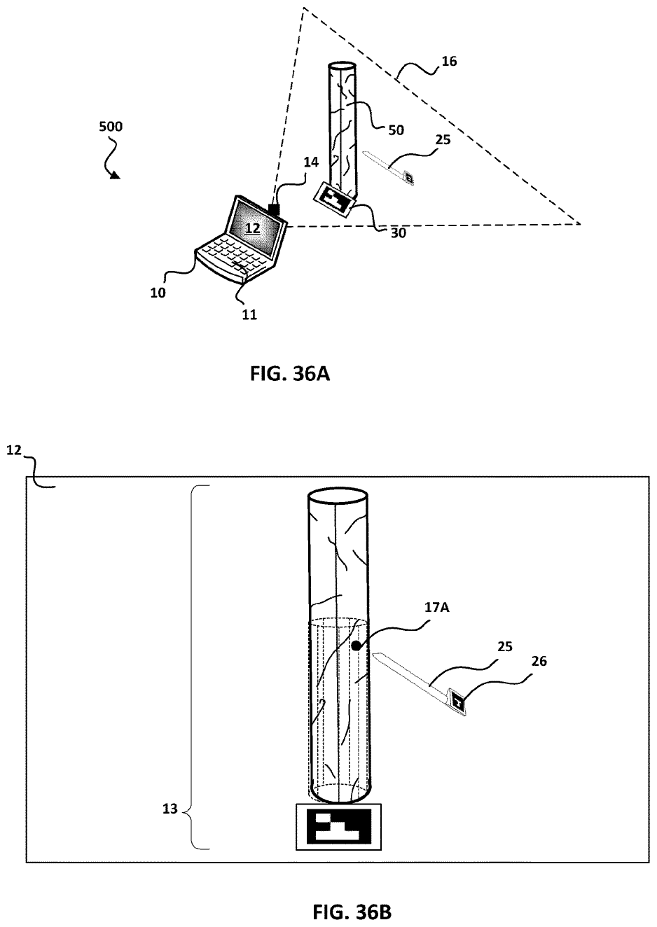

FIG. 36A is a schematic diagram of a structural data logging system 500, according to an example. System 500 is similar to system 5. In particular, in this example, system 500 includes a digital video camera 14, a display device 12, and a user input device 11—in this example a computer keyboard. System 500 also includes an additional user input device 25, which takes the form of a pointer affixed to which is a machine-readable code 26 (see FIG. 36B). Device 25 has a proximal end at which machine readable-code 26 is affixed, and a distal end at the opposite end of its body. Device 25 can be held by a user in a manner similar to a pen. While machine-readable code 26 is, along with machine-readable code 30, within the field of view 16 of camera 14, its distal end may be touched to selected locations on object 50. As the distal end of device 25 is moved, due to its fixed pose (3D location; orientation) with respect to machine-readable code 26 at its proximal end, machine-readable code 26 is moved also. Generally-speaking, a unique pose in the field of view 16 of the distal end of device 25 will correspond to a unique pose in the field of view 16 of the proximal end of device 25. Therefore, in each frame of digital video captured by camera 14 that is processed, machine-readable code 26 may be detected and its pose determined. This pose may be transformed into a pose of the distal end of device 25, and thus into the point in 3D space relative to the 3D model at which distal end resides in the frame. As explained herein, a user may hold device 25 in a desired position and signal system 500 to register the frame(s) being captured while device 25 is being held in this desired position. In turn, system 500 processes the frame(s) to determine a pose of machine-readable code 25, and thus can transform this pose into the pose of the distal end device 25. The pose of the distal end of device 25 can be registered as a feature 17A. In FIG. 36B, feature 17A—a 3D point—has been registered following the positioning of device 25 to arrange the distal end of device 25 against a desired point on object 50, and the signaling of system 500 to capture that point. In examples, such signaling may be done using an actuator on device 25 itself that causes electronic components in device 25 to send a capture signal either wirelessly or by wire to processor 12. In other examples, such signaling may be done using a foot pedal or other actuator that can communicate either wirelessly or by wire with computer 10.

In examples, system 500 also includes another user input device that is a mouse (not shown in FIG. 36A). Digital video camera 14, display device 12, and certain of the user input devices are integrated as part of the packaging of a laptop computer 10. Laptop computer 10 includes several components as would be known to a person of ordinary skill in general purpose computing, such as at least one processor and system memory, as has been described herein.

Like in other examples, in this example, the at least one processor is additionally configured as a particular special purpose computer for logging of structure data in a number of ways, as described herein. In particular, the at least one processor is in communication with digital video camera 14, display device 12, and any input devices such as user input device 11 and user input device 25, and is configured to receive video frames captured by the digital video camera and, during receipt of the video frames, display the video frames on display device 12. Furthermore, the at least one processor is configured to process the video frames to detect at least one predetermined machine-readable code, such as code 30 and/or code 26, that may have been captured in the region of interest 16 captured within the field of view of digital video camera 14. The at least one processor is also configured to, in the event that the at least one predetermined machine-readable code 30 is detected, determine a pose (i.e., a position and orientation relative to, for example, digital video camera 14) of the at least one machine-readable code 30, and receive, via the at least one user input device such as user input device 11 or user input device 25 (detected by camera 14 and the processor using machine-readable code 26), one or more user selections corresponding to a respective pixel on display device 12. Furthermore, the at least one processor is configured to, based at least on the pose of the at least one machine-readable code 30 at the time each of the one or more user selection is received, calculate a respective 3D coordinate of a corresponding point within a digital 3D model of an object. The at least one processor is also configured to augment the digital 3D model with a respective feature at the 3D coordinate.

System 500 is provided to enable a user to visually register a representation of a digital 3D model of an object that is displayed on display device 12 with a physical object in the region of interest that is captured by digital video camera 14 and displayed in conjunction with the representation of the digital 3D model. As explained, the digital 3D model is not anchored to any object in the region of interest 16, except for the at least one predetermined machine-readable code 30. If code 30 is not detected by system 500 in a video frame, then no representation of the digital 3D model is displayed, even if the object 50 to which the digital 3D model is intended to correspond is within the region of interest 16. Furthermore, even if object 50 to which the digital 3D model is intended to correspond is not within region of interest 16, a representation of digital 3D model may be displayed as long as predetermined machine-readable code 30 can be detected within the video frames. The anchoring of the digital 3D model to the predetermined code 30 in this way provides significant easing of processing by system 500 of video frames, because system 500 is required only to detect the predetermined machine readable code 30 and, if it is present, machine-readable code 26, and to determine a respective pose.

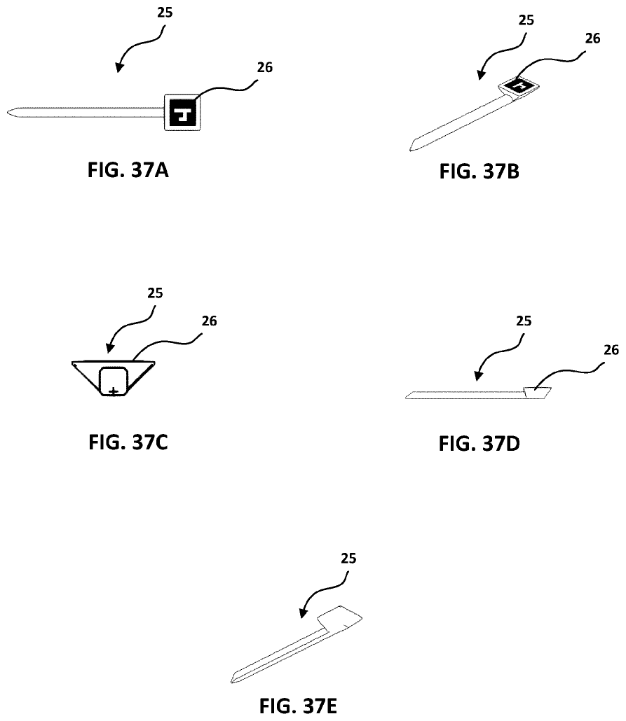

FIG. 37A is a top plan view of user input device 25, showing machine-readable code 26 at a proximal end and a tapered point at a distal end opposite the proximal end for precisely contacting particular locations on an object to identify feature points and/or provisional points. FIG. 37B is a front perspective view of user input device 25. FIG. 37C is a distal end view of user input device 25 looking from the distal end towards the proximal end. FIG. 37D is a side elevation view of user input device 25. FIG. 37E is a rear perspective view of user input device 25. It will be appreciated that, if the digital video camera 14 sees, within field of view 16, input device 25 in the pose shown in FIGS. 37C, 37D and 37E, then machine-readable code 26 will not be captured, or sufficiently captured, within video frames to allow system 500 to determine the pose of machine-readable code 26. As such, a user may wish to bear this in mind when orienting and position device 25 during use. Alternatively, multiple unique machine-readable codes may be affixed to device 25 to enable device 25 to be posed more flexibly while still enabling system 500 to capture digital video frames with one or more discernable ones of the affixed machine-readable codes.

Although examples have been described, those of skill in the art will appreciate that variations and modifications may be made without departing from the spirit, scope and purpose of the invention as defined by the appended claims.

For example, while in examples described herein the objects may be cylindrical or part-cylindrical in shape, or at least correspond generally to (or logically fit within) a cylindrical envelope, alternatives are possible in which more generic structural data can be extracted from non-core rock specimens, such as outcrops, underground openings, and other non-core rock specimens. In such a case, the machine-readable code may not necessarily be hosted on a hand tool such as that described herein, but may be a board with a machine-readable code and an object-receiving surface on which the non-core object may be placed for logging. A plane with a known spatial orientation may be defined by the board, and a plane with the line of maximum dip drawn by the user providing picking points within such line to determine the coordinate system relationship between the plane and the hand tool may be used. Alternative examples are possible.

Furthermore, while in examples described herein the hand tool presents multiple code-presenting surfaces each having at least one respective machine-readable code, implementations are contemplated in which an alternative hand tool presents only one code-presenting surface having only one machine-readable code.

1. A structural data logging system comprising:
a digital video camera;
a display device;
at least one user input device; and
at least one processor in communication with at least the digital video camera and the display device, and configured to:
receive video frames captured by the digital video camera;
during receipt of the video frames:
display the video frames on the display device;
process the video frames to detect at least one predetermined machine-readable code; and
in the event that the at least one predetermined machine-readable code is detected:
determine a pose of the at least one machine-readable code;
receive, using the at least one user input device, one or more user selections corresponding to a respective pixel on the display device;
based at least on the pose of the at least one machine-readable code at a time each of the one or more user selection is received, calculate a respective three-dimensional (3D) coordinate of a corresponding point within a digital 3D model of an object; and
augment the digital 3D model with a respective feature at the 3D coordinate.

2. The structural data logging system of claim 1, wherein calculating is additionally based on a scale of the at least one predetermined machine-readable code.

3. The structural data logging system of claim 1, wherein the digital 3D model is a digital 3D model of a cylinder having a length and a radius.

4. The structural data logging system of claim 3, wherein the at least one processor is configured to receive from a user, using the at least one user input device, at least a value of the radius.

5. The structural data logging system of claim 1, wherein the at least one processor is further configured to:
generate a 2D visual representation of the digital 3D model based on the pose of the at least one machine-readable code at a time of the generating.

6. The structural data logging system of claim 5, wherein the 2D visual representation of the digital 3D model comprises portions including at least:
a wireframe portion representing an envelope of the digital 3D model; and
a feature portion representing one or more features of the digital 3D model.

7. The structural data logging system of claim 6, wherein the portions further comprise:
at least one feature label corresponding to a respective feature.

8. The structural data logging system of claim 5, wherein the at least one processor is further configured to:
display the 2D visual representation on the display device.

9. The structural data logging system of claim 6, wherein the at least one processor is further configured to:
display a selected at least one of the portions of the 2D visual representation on the display device responsive to a user instruction received using the at least one user input device.

10. The structural data logging system of claim 1, wherein the respective feature is a 3D coordinate in the digital 3D model and the at least one processor is further configured to:
associate the 3D coordinate with one or more other 3D coordinates of the digital 3D model determined based on one or more prior user selections using the at least one user input device, thereby to augment the digital 3D model with a respective structure defined by multiple associated 3D coordinates.

11. The structural data logging system of claim 10, wherein the respective structure is one of: a line defined by at least two associated 3D coordinates representing a structural line; a plane defined by two associated 3D coordinates derived from a major axis of a projected ellipse major axis; and a plane defined by at least three associated 3D coordinates.

12. The structural data logging system of claim 1, wherein the at least one processor is configured to:
receive, using the at least one user input device, first and second user selections corresponding to respective pixels on the display device;
based at least on the pose of the at least one machine-readable code at a time the first user selection is received, calculate a respective 3D position of a corresponding first provisional point within the digital 3D model;
based at least on the pose of the at least one machine-readable code at a time the second user selection is received, calculate a respective 3D position of a corresponding second provisional point within the digital 3D model;
generate a first vector passing through a 3D position of the digital video camera and the first provisional point;
generate a second vector passing through a 3D position of the digital video camera and the second provisional point;
calculate a respective 3D intersection position of the first vector and the second vector;
and augment the digital 3D model with a respective feature at the 3D intersection position.

13. The structural data logging system of claim 12, wherein the 3D intersection position is one of:
a 3D point that is common to both the first vector and the second vector intersect; and
a 3D point along the shortest line between the first vector and the second vector.

14. The structural data logging system of claim 13, wherein the 3D point along the shortest line between the first vector and the second vector is the 3D point at a midpoint of the shortest line between the first vector and the second vector.

15. The structural data logging system of claim 1, further comprising:
a hand tool having a rigid body defining:
an object-receiving surface; and
at least one code-presenting surface,
wherein the object-receiving surface is dimensioned to interface with a physical object for which structural data is to be logged, and
wherein the at least one code-presenting surface presents a respective one of the at least one predetermined machine-readable codes.

16. (canceled)

17. (canceled)

18. (canceled)

19. The structural data logging system of claim 15, wherein the object-receiving surface is dimensioned to interface with a drill core sample as the object, the object-receiving surface comprising a vertical line for aligning the object-receiving surface with a reference line of the drill core sample, and a horizontal extent for aligning the object-receiving surface with particular positions along a length of the drill core sample.

20. The structural data logging system of claim 19, wherein the object-receiving surface is dimensioned to interface with drill core samples having a range of radii.

21. The structural data logging system of claim 19, wherein the at least one processor is configured to:
receive from a user, using the at least one user input device, at least a value corresponding to a current position along the length of the drill core sample, wherein re-alignment by a user of the object-receiving surface with a different particular position along the length of the drill core sample corresponds to a different respective position along the length of the 3D digital model.

22. (canceled)

23. (canceled)

24. (canceled)

25. (canceled)

26. A computer-implemented structural data logging method comprising:
receiving video frames captured by a digital video camera;
during receipt of the video frames:
displaying the video frames on a display device;
processing the video frames to detect at least one predetermined machine-readable code;
in the event that the at least one predetermined machine-readable code is detected:
determining a pose of the at least one machine-readable code;
receiving, using at least one user input device, one or more user selections corresponding to a respective pixel on the display device;
based at least on the pose of the at least one machine-readable code at a time each of the one or more user selection is received, calculating a respective three-dimensional (3D) coordinate of a corresponding point within a digital 3D model of an object; and
augmenting the digital 3D model with a respective feature at the 3D coordinate.

27. A non-transitory computer readable medium embodying a computer program executable on a computing system for structural logging, the computer program comprising:
computer program code for receiving video frames captured by a digital video camera; and
computer program code for, during receipt of the video frames:
displaying the video frames on a display device;
processing the video frames to detect at least one predetermined machine-readable code;
in the event that the at least one predetermined machine-readable code is detected:
determining a pose of the at least one machine-readable code;
receiving, using at least one user input device, one or more user selections corresponding to a respective pixel on the display device;
based at least on the pose of the at least one machine-readable code at a time each of the one or more user selection is received, calculating a respective three-dimensional (3D) coordinate of a corresponding point within a digital 3D model of an object; and
augmenting the digital 3D model with a respective feature at the 3D coordinate.
